(19) United States
(12) Patent Application Publication
(10) Pub. No.: US 2026/0313905 A1
(43) Pub. Date: Oct. 8, 2026

(54) SEMICONDUCTOR DEVICES INCLUDING GUARD RING STRUCTURE AND DATA STORAGE SYSTEMS INCLUDING THE SAME

(71) Applicant: Samsung Electronics Co., Ltd., Suwon-si (KR)

(72) Inventors: Kangmin Kim, Suwon-si (KR); Juhae Park, Suwon-si (KR); Seongwan Hong, Suwon-si (KR)

(73) Assignee: Samsung Electronics Co., Ltd., Suwon-si (KR)

(21) Appl. No.: 19/369,835

(22) Filed: Oct. 27, 2025

(30) Foreign Application Priority Data
Apr. 7, 2025 (KR) 10 2025 0044872

(51) Int. Cl. H10B 43/50; H01L 23/00; H01L 23/58; H10B 41/27; H10B 41/35; H10B 41/50; H10B 43/27; H10B 43/35

(52) U.S. Cl. CPC H10B 43/50; H10B 41/27; H10B 41/35; H10B 41/50; H10B 43/27; H10B 43/35; H10W 42/00; H10W 42/121

(57) ABSTRACT

In example embodiments, provided is a semiconductor device including: a guard ring structure surrounding an active region and penetrating through a cell region insulating layer and an upper insulating layer, and the guard ring structure includes: a first structure including a first body portion penetrating through the cell region insulating layer and extending in a second direction, substantially perpendicular to the first direction, and first protrusion portions protruding from an upper surface of the first body portion and spaced apart from one another; and a second structure including second body portion penetrating through the upper insulating layer so as to overlap the first structure in the first direction on the first structure, and second protrusion portions protruding from a lower surface of the second body portion and spaced apart from one another, and the first protrusion portions and the second protrusion portions are disposed alternately in the second direction.

### CROSS-REFERENCE TO RELATED APPLICATIONS

This present application claims priority to and the benefit under 35 U.S.C. § 119(a)-(d) of Korean Patent Application No. 10-2025-0044872, filed on Apr. 7, 2025, in the Korean Intellectual Property Office, the entire disclosure of which is incorporated herein by reference.

### FIELD

The present disclosure relates to semiconductor devices and data storage systems including the same.

### BACKGROUND

In a data storage system requiring data storage, a semiconductor device capable of storing a large amount of data is required. Accordingly, a method of increasing the data storage capacity of a semiconductor device has been researched. For example, as one method of increasing the data storage capacity of a semiconductor device, a semiconductor device including memory cells arranged three-dimensionally, instead of two-dimensionally arranged memory cells, has been proposed.

### SUMMARY

Aspects of the present disclosure provide a data storage system including a semiconductor device having improved reliability.

A semiconductor device according to example embodiments may include: a substrate including an active region and an edge region surrounding the active region; a stack structure including a plurality of gate electrodes stacked and spaced apart from one another in a first direction, substantially perpendicular to an upper surface of the substrate, in the active region; a channel structure penetrating through the stack structure in the first direction and including a channel layer; a cell region insulating layer disposed in the edge region; an upper insulating layer disposed on the cell region insulating layer; and a guard ring structure surrounding the active region and penetrating through the cell region insulating layer and the upper insulating layer, in the edge region, and the guard ring structure may include: a first structure including a first body portion penetrating through the cell region insulating layer from the substrate and extending in a second direction, substantially perpendicular to the first direction, and first protrusion portions protruding from an upper surface of the first body portion and spaced apart from one another; and a second structure including second body portion penetrating through the upper insulating layer so as to overlap the first structure in the first direction on the first structure, and second protrusion portions protruding from a lower surface of the second body portion and spaced apart from one another, and the first protrusion portions and the second protrusion portions may be disposed alternately in the second direction.

A semiconductor device according to example embodiments may include: a substrate including an active region and an edge region surrounding the active region; a stack structure including a plurality of gate electrodes stacked and spaced apart from one another in a first direction, substantially perpendicular to an upper surface of the substrate in the active region; a channel structure penetrating through the stack structure in the first direction and including a channel layer; a cell region insulating layer disposed in the edge region; an upper insulating layer disposed on the cell region insulating layer; an inner guard ring structure surrounding the active region, penetrating through the cell region insulating layer and the upper insulating layer, and extending in a second direction, substantially perpendicular to the first direction, in the edge region; and an outer guard ring structure surrounding the inner guard ring structure and spaced apart from the inner guard ring structure in a third direction, substantially perpendicular to the first direction and the second direction, and each of the inner guard ring structure and the outer guard ring structure may include: a first structure including a first body portion penetrating through the cell region insulating layer from the substrate and extending in the second direction, first protrusion portions protruding from an upper surface of the first body portion and spaced apart from one another, and first recess portions between the first protrusion portions; and a second structure penetrating through the upper insulating layer so as to overlap the first structure in the first direction on the first structure, and the first recess portions of the inner guard ring structure may be offset from the first recess portions of the outer guard ring structure in the third direction.

A data storage system may include: a semiconductor device including an input/output pad; and a controller electrically connected to the semiconductor device through the input/output pad and configured to control the semiconductor device, and the semiconductor device may include: a substrate including an active region and an edge region surrounding the active region; a stack structure including a plurality of gate electrodes stacked and spaced apart from one another in a first direction, substantially perpendicular to an upper surface of the substrate in the active region; a channel structure penetrating through the stack structure in the first direction and including a channel layer; a cell region insulating layer disposed in the edge region; an upper insulating layer disposed on the cell region insulating layer; an inner guard ring structure surrounding the active region, penetrating through the cell region insulating layer and the upper insulating layer, and extending in a second direction, substantially perpendicular to the first direction, in the edge region; and an outer guard ring structure surrounding the inner guard ring structure and spaced apart from the inner guard ring structure in a third direction, substantially perpendicular to the first and second directions, and each of the inner guard ring structure and the outer guard ring structure may include: a first structure including a first body portion penetrating through the cell region insulating layer from the substrate and extending in the second direction, first protrusion portions protruding from an upper surface of the first body portion and spaced apart from one another, and first recess portions between the first protrusion portions; and a second structure penetrating through the upper insulating layer so as to overlap the first structure in the first direction on the first structure, and the first recess portions of the inner guard ring structure may have a structure that is offset from the first recess portions of the outer guard ring structure in the third direction.

A method of manufacturing a semiconductor device according to example embodiments may include: forming a mold structure by alternately stacking interlayer insulating layers and sacrificial insulating layers in a first direction, substantially perpendicular to an upper surface of a substrate; forming a cell region insulating layer in an edge region surrounding the mold structure; forming vertical sacrificial structures penetrating through the mold structure in the first direction; forming a sacrificial guard ring structure penetrating through the cell region insulating layer in the first direction and surrounding the mold structure; forming a stack structure by replacing the sacrificial insulating layers of the mold structure with a gate electrode; forming a first upper insulating layer on the stack structure and the cell region insulating layer; forming a first opening exposing an upper surface of the sacrificial guard ring structure, in the first upper insulating layer; forming a guard ring opening by removing the sacrificial guard ring structure from the first openings, and forming a first structure filling the guard ring opening and the first openings; forming a second upper insulating layer on the first structure and the first upper insulating layer; forming a second opening exposing an upper surface of the first structure, in the second upper insulating layer; and forming a guard ring structure by filling the second opening and forming a second structure extending in the first direction with the first structure.

In the forming the first opening in the first upper insulating layer, the first openings may be formed to be spaced apart from the upper surface of the sacrificial guard ring structure by a first separation distance.

In the forming the first opening, the first upper insulating layer may remain at a first separation distance of the first openings.

The forming the first opening may include an operation of forming openings exposing some of the vertical sacrificial structures, on the vertical sacrificial structures.

In the forming the second opening in the second upper insulating layer, the second opening may be formed to include a first opening region penetrating through the second upper insulating layer along the first structure and a second opening region in which the first upper insulating layer remaining below the first opening region is removed.

In the forming the second opening in the second upper insulating layer, a first upper insulating pattern may be formed between a side surface of the second opening region and the first structure.

The forming the second opening in the second upper insulating layer may further include an operation of forming a third opening region by removing the first upper insulating pattern.

The forming the first structure may include an operation of forming a first body portion filling the guard ring opening and first protrusion portions filling the first openings.

The forming the second structure may include an operation of forming a second body portion filling the first opening region and an operation of forming second protrusion portions by filling the third opening region.

The forming the second structure may include: an operation of stacking a diffusion barrier surrounding side surfaces and lower surfaces of the first opening region and the third opening region, and an operation of stacking a metal layer filling the first opening region and the third opening region together on the diffusion barrier.

The first protrusion portions and the second protrusion portions may be alternately disposed between the first body portion and the second body portion, and the diffusion barrier may be disposed between the first protrusion portions and the second protrusion portions.

According to example embodiments, in a guard ring structure penetrating through a cell region insulation layer and an upper insulation layer, when a sacrificial guard ring structure is removed to form a guard ring opening having a high aspect ratio, at least a portion of an upper insulation layer may remain on the guard ring opening, thereby preventing a leaning phenomenon of the guard ring structure. Accordingly, a semiconductor device having improved reliability and a data storage system including the same may be provided without increasing a size of the guard ring structure or securing a large separation distance.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a schematic plan view of a semiconductor device according to example embodiments;

FIGS. 2A and 2B are schematic cross-sectional views of a semiconductor device according to example embodiments;

FIGS. 3A and 3B are a schematic partial enlarged view and an exploded perspective view illustrating partial regions of a semiconductor device according to example embodiments, respectively;

FIGS. 4 to 7 are schematic cross-sectional views of a semiconductor device according to example embodiments;

FIGS. 8 and 9 are schematic cross-sectional views of a semiconductor device according to example embodiments;

FIGS. 10A to 10H, and 11A to 11E are schematic cross-sectional views illustrating a method of manufacturing a semiconductor device according to example embodiments;

FIG. 12 is a schematic view of a data storage system including a semiconductor device according to example embodiments of the present disclosure; and

FIG. 13 is a perspective view schematically illustrating a data storage system including a semiconductor device according to example embodiments of the present disclosure.

### DETAILED DESCRIPTION

Hereinafter, example embodiments of the present disclosure will be described with reference to the accompanying drawings. Hereinafter, the terms ‘above,’ ‘upper portion,’ ‘upper surface,’ ‘below,’ ‘lower portion,’ ‘lower surface,’ ‘side surface,’ and the like, may be understood as being indicated based on the accompanying drawing, except that they are indicated by drawing references and referred to separately.

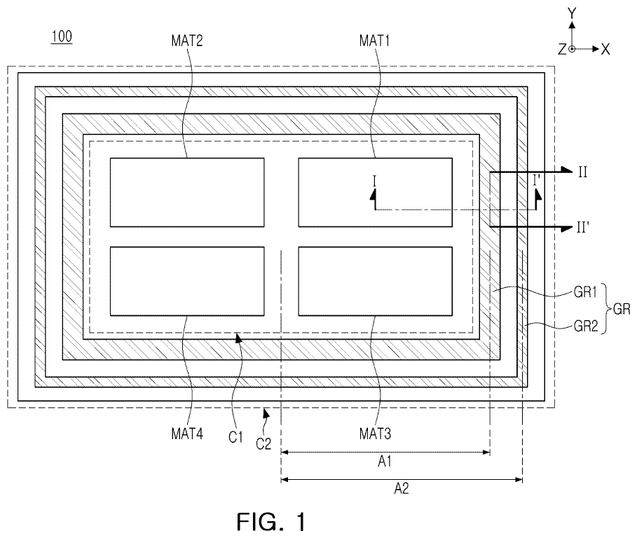

FIG. 1 is a schematic plan view of a semiconductor device according to example embodiments.

Referring to FIG. 1, a semiconductor device 100 may have an active region C1 in which stack structures or mold structures are disposed on a semiconductor substrate 101, and an edge region C2 surrounding the active region C1.

The active region C1 may be disposed in a central region of the semiconductor substrate 101 to occupy most of an area of the semiconductor device and may include a plurality of mats MAT1 to MAT4.

The plurality of mats MAT1 to MAT4 may include a plurality of memory blocks. Each of the plurality of memory blocks may include a plurality of cell strings. For example, one of the memory blocks included in a first mat MAT1 may include channel structures CH corresponding to a plurality of cell strings. The plurality of channel structures CH included in one mat may be formed on a plurality of planes.

The mats MAT1 to MAT4 may be arranged in a matrix type in an X-direction and a Y-direction, and the plurality of mats MAT1 to MAT4 may have substantially the same structure, and may be disposed symmetrically toward a center thereof.

A cell region insulating layer 190 may be disposed in the edge region C2 to cover a portion of the mold structure or the stack structure. At least one guard ring structure GR may be disposed in the edge region C2 to penetrate through the cell region insulating layer 190. At least one guard ring structure GR may be spaced apart from the active region C1 and may extend to surround the active region C1. On an X-Y plane, the guard ring structures GR may extend to have a closed loop type, and may have, for example, a frame shape or a ring shape. A planar shape of the guard ring structures GR may be determined by a shape of the active region C1.

A direction perpendicular to an upper surface of the semiconductor substrate 101 may be defined as a vertical direction (Z-direction) or the first direction, and an extension direction of the guard ring structures GR may be defined as a D1 direction (e.g., a second direction) on the X-Y plane, which is a plane perpendicular to the Z-direction. Accordingly, when the guard ring structure GR has a frame shape in which the guard ring structure GR extends in the X-direction on the X-Y plane and is bent, extends in the Y-direction and is bent again, extends in the X-direction and is bent again, and extends in the Y-direction, the D1 direction (e.g., the second direction) may be defined as a length direction in which the guard ring structure GR extends in the X-Y plane, which is not in either the X-direction or the Y-direction. Additionally, as a width direction of the guard ring structure GR on the X-Y plane, a direction perpendicular to the D1 direction (e.g., the second direction) may be defined as a D2 direction (e.g., a third direction).

At least one of the guard ring structures GR may include an inner guard ring structure GR1 that is close to the active region C1 and surrounds the active region C1 and an outer guard ring structure GR2 that is spaced apart from the inner guard ring structure GR1 and surrounds the inner guard ring structure GR1.

The outer guard ring structure GR2 may have a distance A2 from a center of the semiconductor device 100 to a center of a width of the outer guard ring structure GR2 greater than a distance A1 from the center of the semiconductor device 100 to a center of a width of the inner guard ring structure GR1. The outer guard ring structure GR2 may have a shape similar to the inner guard ring structure GR1, and may be concentric with respect to the center of the semiconductor device 100. That is, the inner guard ring structure GR1 extends in the D1 direction (e.g., the second direction) with the same width, and the outer guard ring structure GR2 also extends in the D1 direction (e.g., the second direction) with the same width. Additionally, a separation distance between the inner guard ring structure GR1 and the outer guard ring structure GR2 may be maintained to be the same.

A width in the D2 direction (e.g., the third direction) from an upper surface of the inner guard ring structure GR1 may be greater than a width of the outer guard ring structure GR2 in the D2 direction (e.g., the third direction).

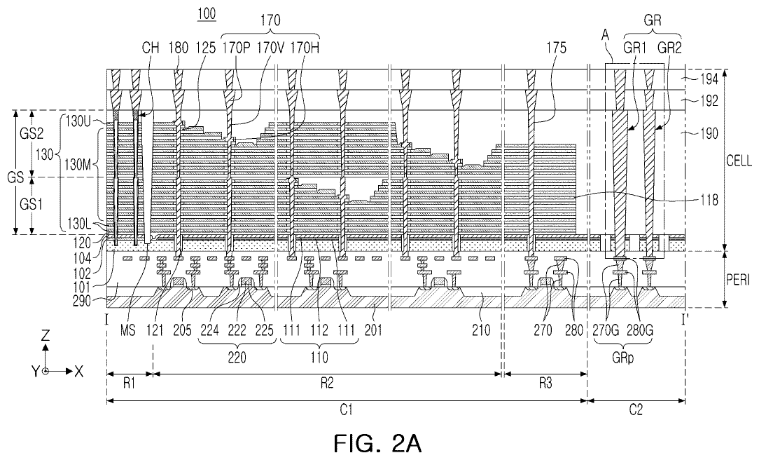

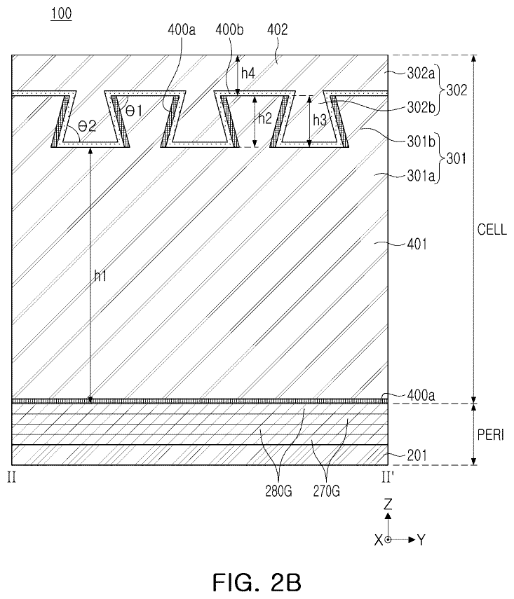

FIGS. 2A and 2B are schematic cross-sectional views of a semiconductor device according to example embodiments. FIGS. 2A and 2B illustrate cross-sections along the cutting lines I-I′ and II-II′ of FIG. 1, respectively.

Referring to FIG. 2A, the semiconductor device 100 may include a peripheral circuit region PERI, which is a first semiconductor structure including a substrate 201, and a memory cell region CELL, which is a second semiconductor structure including a semiconductor substrate 101. The memory cell region CELL may be disposed on the peripheral circuit region PERI. In example embodiments, the memory cell region CELL may be disposed below the peripheral circuit region PERI.

The peripheral circuit region PERI may include a substrate 201, impurity regions 205 and element isolation layers 210 within the substrate 201, circuit elements 220 disposed on the substrate 201, a peripheral region insulating layer 290, circuit contact plugs 270, and circuit interconnection lines 280.

The substrate 201 may have an upper surface extending in the X-direction and the Y-direction. The active region C1 may be defined by the element isolation layers 210 on the substrate 201. The impurity regions 205 including impurities may be disposed in a portion of the active region C1. The substrate 201 may include a semiconductor material, such as a group IV semiconductor, a group III-V compound semiconductor, or a group II-VI compound semiconductor. The substrate 201 may be provided as a bulk wafer or an epitaxial layer.

The circuit elements 220 may include a planar transistor. Each of the circuit elements 220 may include a circuit gate dielectric layer 222, a spacer layer 224, and a circuit gate electrode 225. The impurity regions 205 may be disposed as source/drain regions within the substrate 201 on both sides of the circuit gate electrode 225.

The peripheral region insulating layer 290 may be disposed on the circuit element 220 on the substrate 201. The peripheral region insulating layer 290 may include a plurality of insulating layers formed in different process stages. The peripheral region insulating layer 290 may be formed of an insulating material.

The circuit contact plugs 270 and the circuit interconnection lines 280 may form a circuit interconnection structure electrically connected to the circuit elements 220 and the impurity regions 205. The circuit contact plugs 270 may have a cylindrical shape, and the circuit interconnection lines 280 may have a line shape. An electrical signal may be applied to the circuit element 220 by the circuit contact plugs 270 and the circuit interconnection lines 280. In a region not shown, the circuit contact plugs 270 may also be connected to the circuit gate electrode 225. The circuit interconnection lines 280 may be connected to the circuit contact plugs 270, may have a line shape, and may be disposed in the form of a plurality of layers. The circuit contact plugs 270 and the circuit interconnection lines 280 may include a conductive material, and may include, for example, tungsten (W), copper (Cu), and aluminum (Al), and each of the components may further include a diffusion barrier. In example embodiments, the number of layers of the circuit contact plugs 270 and the circuit interconnection lines 280 may be variously changed.

A peripheral guard ring structure (GRp: 270G, 280G) may be disposed in the peripheral circuit region PERI of the edge region C2. The peripheral guard ring structure GRp is a vertical structure extending from the substrate 201 to each guard ring structure GR, and may be interconnection structures overlapping one another in the X-direction and having a closed loop shape in a plane.

The peripheral guard ring structure GRp may include a conductive material, and may include, for example, tungsten (W), copper (Cu), and aluminum (Al).

The memory cell region CELL may include an active region C1 and an edge region C2. The active region C1 includes a first region R1, a second region R2, a third region R3.

The memory cell region CELL may include a source structure SS, gate electrodes 130 stacked on the source structure SS to form a gate structure GS, interlayer insulating layers 120 alternately stacked with the gate electrodes 130, a cell region insulating layer 190 covering the gate structure, channel structures CH, contact plugs 170, and guard ring structures GR.

The first region R1 may be a region in which the gate structure is disposed and channel structures CH penetrating through the vertically stacked gate electrodes 130 are disposed, and may be a region in which memory cells are disposed.

The second region R2 may correspond to a region in which the gate structure is disposed and the contact plugs 170 for electrically connecting the memory cells to the peripheral circuit region PERI are disposed. To this end, the gate electrodes 130 may extend by different lengths, but the present disclosure is not limited thereto. The second region R2 may be disposed at least at one end of the first region R1 in at least one direction, for example, the X-direction.

The third region R3 may include a mold structure formed of an insulating material, in which the gate electrode 130 fails to extend or be disposed, and may have through-contact plug 175 directly transmitting signals from the outside to the peripheral region disposed therein. The third region R3 may include interlayer insulating layers 120 and sacrificial insulating layers 118 alternately stacked on the upper surface of the semiconductor substrate 101. The sacrificial insulating layers 118 may be disposed on substantially the same height level as the gate electrodes 130.

The interlayer insulating layers 120 and the sacrificial insulating layers 118 included in the third region R3 may be formed of an insulating material. For example, each of the interlayer insulating layers 120 and the sacrificial insulating layers 118 may include silicon oxide, silicon nitride, or silicon oxynitride.

In the edge region C2, the cell region insulating layer 190 may be disposed, and at least one guard ring structure GR extending in a vertical direction from an upper surface of the memory cell region CELL to the substrate 201 and surrounding the active region C1 may be disposed.

The source structure SS may include a semiconductor substrate 101, a first horizontal conductive layer 102, and a second horizontal conductive layer 104, which are sequentially stacked in the first region R1. However, in example embodiments, the number of conductive layers of the source structure SS may be variously changed.

The semiconductor substrate 101 may have a plate shape and may function as at least a portion of a common source line of the semiconductor device 100. The semiconductor substrate 101 may have an upper surface extending in the X-direction and the Y-direction. The semiconductor substrate 101 may include a conductive material. For example, the semiconductor substrate 101 may include a semiconductor material, such as a group IV semiconductor, a group III-V compound semiconductor, or a group II-VI compound semiconductor. For example, the group IV semiconductor may include silicon, germanium, or silicon-germanium. The semiconductor substrate 101 may further include impurities. The semiconductor substrate 101 may be provided as a polycrystalline semiconductor layer, such as a polycrystalline silicon layer, or an epitaxial layer.

The first and second horizontal conductive layers 102 and 104 may be sequentially stacked and disposed on the upper surface of the semiconductor substrate 101 in the first region R1. The first horizontal conductive layer 102 may not extend to the second region R2, and the second horizontal conductive layer 104 may extend to the second region R2 and the third region R3. The first horizontal conductive layer 102 may function as a portion of a common source line of the semiconductor device 100, and may function as, for example, a common source line together with the semiconductor substrate 101. The first horizontal conductive layer 102 may be directly connected to a channel layer 140 around the channel layer 140. The second horizontal conductive layer 104 may be in contact with the semiconductor substrate 101 in some regions of the second region R2 in which the first horizontal conductive layer 102 and a horizontal sacrificial layer 110 are not disposed.

The first and second horizontal conductive layers 102 and 104 may include a semiconductor material, and may include, for example, polycrystalline silicon. In this case, at least the first horizontal conductive layer 102 may be a layer doped with impurities having the same conductivity type as the semiconductor substrate 101, and the second horizontal conductive layer 104 may be a doped layer or a layer including impurities diffused from the first horizontal conductive layer 102. However, a material of the second horizontal conductive layer 104 is not limited to a semiconductor material, and may also be replaced with an insulating layer.

The horizontal sacrificial layer 110 may be disposed on the semiconductor substrate 101 on the same level as a level of the first horizontal conductive layer 102 in at least a portion of the second region R2. The horizontal sacrificial layer 110 may include first and second horizontal sacrificial layers 111 and 112 alternately stacked on the second region R2 of the semiconductor substrate 101. The horizontal sacrificial layer 110 may be a layer remaining after a portion of sacrificial layer is replaced with the first horizontal conductive layer 102 during a manufacturing process of the semiconductor device 100.

The horizontal sacrificial layer 110 may include silicon oxide, silicon nitride, silicon carbide, or silicon oxynitride. The first horizontal sacrificial layers 111 and the second horizontal sacrificial layer 112 may include different insulating materials. For example, the first horizontal sacrificial layers 111 may be formed of the same material as the interlayer insulating layers 120, and the second horizontal sacrificial layer 112 may be formed of a different material from the interlayer insulating layers 120.

Substrate insulating layers 121 may be disposed to penetrate through the semiconductor substrate 101, the horizontal sacrificial layer 110 and the second horizontal conductive layer 104 in a portion of the second region R2. The substrate insulating layers 121 may be further disposed in the first region R1, and the substrate insulating layers 121 may also be disposed in a region in which a through-contact plug 175 is disposed in the third region R3. The substrate insulating layers 121 may be disposed in the edge region C2 to physically separate a portion of the semiconductor substrate 101 through which each guard ring structure GR penetrates, from other portions, so that each guard ring structure GR may be insulated from the source structure. The substrate insulating layers 121 may include an insulating material, for example, silicon oxide, silicon nitride, silicon carbide, or silicon oxynitride.

The gate electrodes 130 may be vertically stacked on the semiconductor substrate 101 to form a gate structure GS together with the interlayer insulating layers 120. The gate structure GS may include first and second stack structures GS1 and GS2, which are vertically stacked. However, according to example embodiments, the number of stack structures of the gate structure GS may be variously changed. For example, in some example embodiments, the gate structure GS may be formed of three or more stack structures or may be formed of a single stack structure. The number of gate electrodes 130 of each of the first and second stack structures GS1 and GS2 may be the same or different.

The gate electrodes 130 may include upper gate electrodes 130U of string select transistors, memory gate electrodes 130M of a plurality of memory cells, and lower gate electrodes 130L of an erase transistor and a ground select transistor. The number of memory gate electrodes 130M included in memory cells may be determined depending on the capacity of the semiconductor device 100. One of an upper gate electrode 130U1 and the lower gate electrodes 130L may also be referred to as an upper selection gate electrode and a lower selection gate electrode, respectively. According to example embodiments, each of the upper gate electrode 130U and the lower gate electrodes 130L may be one to four or more, and may have a structure identical to or different from a structure of the memory gate electrodes 130M.

The gate electrodes 130 may be vertically spaced apart from one another and stacked on the first region R1, and may extend from the first region R1 to the second region R2 by different lengths to form staircase-shaped stepped structures.

Separation regions MS may be disposed to penetrate through the stack structure in the Z-direction as illustrated in FIG. 2A and to extend by the first region R1 and the second region R2 in the X-direction. As illustrated in FIG. 2A, the separation regions MS may penetrate through the gate electrodes 130 stacked on the semiconductor substrate 101, may further penetrate through the first and second horizontal conductive layers 102 and 104 below, and may thus be connected to the semiconductor substrate 101. However, in example embodiments, the arrangement shape, the number, and the like, of the separation regions MS are not limited to those illustrated in FIG. 2A.

The separation regions MS may separate the gate electrodes 130 from one another in the Y-direction. The separation regions MS may have a shape in which a width thereof decreases toward the semiconductor substrate 101 due to a high aspect ratio. The separation regions MS may include an insulating material, for example, silicon oxide, silicon nitride, or silicon oxynitride.

Each of the channel structures CH may form one memory cell string, and may be spaced apart from one another while forming rows and columns within the first region R1. The channel structures CH may be disposed to form a lattice pattern or may be disposed in a zigzag shape in one direction. The channel structures CH may include vertically stacked lower and upper channel structures. The channel structures CH may have a form in which the lower channel structures and the upper channel structures are connected, and may have a bent portion due to a difference in width in the connection region. However, according to example embodiments, the number of channel structures stacked in the Z-direction may be variously changed. Each of the channel structures CH may include a channel layer disposed in a channel hole, a gate dielectric layer, a channel buried insulating layer, and a channel pad on an upper end thereof.

Each of the contact plugs 170 may have a form expanded horizontally in the contact region of each gate electrode 130. The contact plug 170 may include a vertical extension portion 170V extending in the Z-direction, a horizontal extension portion 170H extending horizontally from the vertical extension portion 170V and contacting the gate electrode 130, and a head extension portion 170P penetrating through a first upper insulating layer 192 in the Z-direction and connected to a stud 180. The horizontal extension portion 170H may be disposed along a perimeter of the vertical extension portion 170V and an entire side surface thereof may be surrounded by the gate electrode 130. A length from a side surface of the vertical extension portion 170V to an end of the horizontal extension portion 170H may be less than a length from a side surface of the vertical extension portion 170V to outer surfaces of contact insulating layers 125. The contact plugs 170 may be spaced apart from the gate electrodes 130 below the contact regions, i.e., the gate electrodes 130 that are not electrically connected, by the contact insulating layers 125.

The contact plugs 170 may include a conductive material, for example, at least one of tungsten (W), copper (Cu), aluminum (Al), or alloys thereof. In some example embodiments, the contact plugs 170 may include a barrier layer extending in a side surface and a bottom surface, or may have an air gap therein.

The through-contact plug 175 may be disposed within the third region R3 and may extend vertically to an upper surface of the substrate 201 by penetrating through the interlayer insulating layers 120 and the sacrificial insulating layers 118 of the third region R3, and may electrically connect the circuit elements 220 of the memory cell structure CELL and the peripheral circuit structure PERI. The through-contact plug 175 also may include a head extension portion penetrating through the first upper insulating layer 192, and a shape of the head extension portion may be substantially the same as a head extension portion of the contact plug.

The number, shape, and form of the through-contact plugs 175 may be variously changed in example embodiments. The through-contact plugs 175 may include a conductive material, and may include, for example, tungsten (W), copper (Cu), and aluminum (Al).

The cell region insulating layer 190 may be disposed to cover the gate structure and the mold structure of the gate electrodes 130 in the first to third regions R1, R2 and R3 and to fill the edge region C2.

The first upper insulating layer 192 may be disposed on the cell region insulating layer 190 to entirely cover the active region C1 and the edge region C2.

A second upper insulating layer 194 may be disposed on the first upper insulating layer 192. The cell region insulating layer 190 and the first and second upper insulating layers 192 and 194 may be formed of an insulating material.

The studs 180 may penetrate through the second upper insulating layer 194 and may be disposed on the channel structures CH, the contact plugs 170 and the through-contact plugs 175.

The studs 180 may form a cell interconnection structure electrically connected to memory cells in the memory cell region CELL. The studs 180 may be connected to the channel structures CH, the contact plugs 170 and the through-contact plugs 175, and may be electrically connected to the channel structures CH and the gate electrodes 130. The studs 180 are illustrated in a plug shape, but are not limited thereto and may also have a line shape. In example embodiments, the number of plugs and interconnection lines of the cell interconnection structure may be variously changed. The studs 180 may include a metal, and may include, for example, tungsten (W), copper (Cu), and aluminum (Al).

On the channel structures CH, the studs 180 may be connected to lower studs penetrating through the first upper insulating layer 192.

In the edge region C2, the guard ring structures GR extending in the vertical direction from the upper surface of the memory cell region CELL to the semiconductor substrate 101 and surrounding the active region C1 may be disposed.

Each of the guard ring structures GR may be disposed in a closed loop wall type as shown in FIG. 1.

According to example embodiments, the semiconductor device 100 may include an inner guard ring structure GR1 surrounding the active region C1 and an outer guard ring structure GR2 surrounding the inner guard ring structure GR1. The inner guard ring structure GR1 and the outer guard ring structure GR2 may be structures in which lengths in the vertical direction are identical, lengths in the D1 direction (e.g., the second direction) are different, and widths in the D2 direction (e.g., the third direction) are different.

For example, a width of the inner guard ring structure GR1 may be greater than a width of the outer guard ring structure GR2, and as described above, since the inner and outer guard ring structures GR1 and GR2 are concentric, a length of the inner guard ring structure GR1 may be less than a length of the outer guard ring structure GR2.

Each of the inner and outer guard ring structures GR1 and GR2 may penetrate the second horizontal conductive layer 104, the horizontal sacrificial layer 110, and the semiconductor substrate 101, below the cell region insulating layer 190, in the Z-direction, and may be connected to the peripheral guard ring structure GRp within the peripheral circuit region PERI. The peripheral guard ring structures GRp are vertical structures extending from the substrate 201 to each guard ring structure GR, and may be interconnection structures overlapping one another in the Z-direction and having a closed loop shape in a plane.

Accordingly, the peripheral guard ring structures GRp may extend from the peripheral circuit region PERI to the memory cell region CELL, and may extend to a lower portion of the guard ring structures GR, thus forming a protective wall surrounding the active region C1. The guard ring structures GR may function as a moisture oxidation barrier structure and/or a crack stop structure.

Hereinafter, the guard ring structures GR will be described in detail with reference to FIGS. 2B, 3A, 3B and 4.

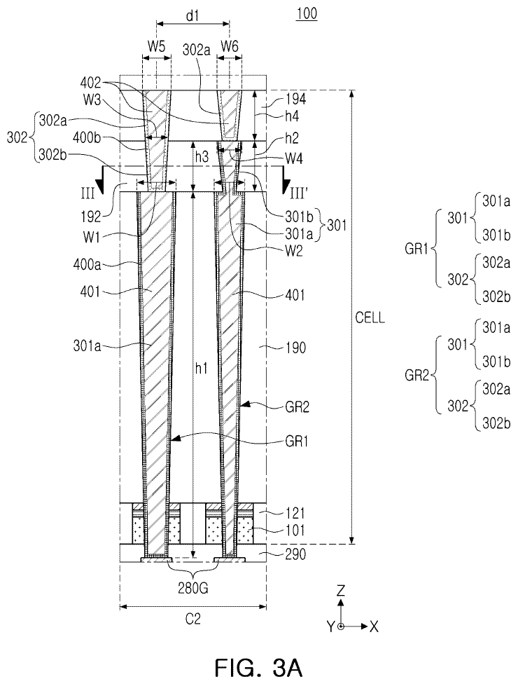

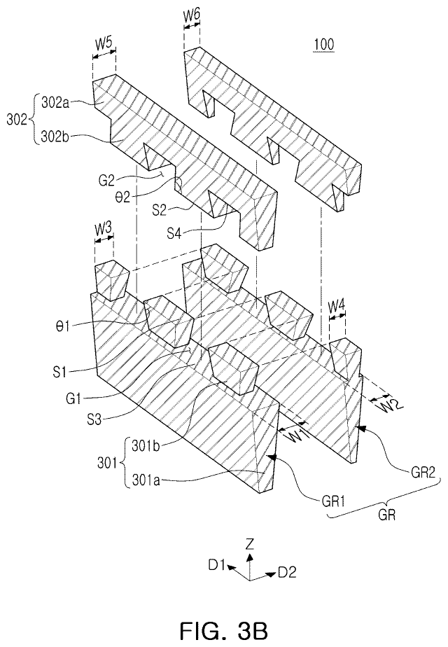

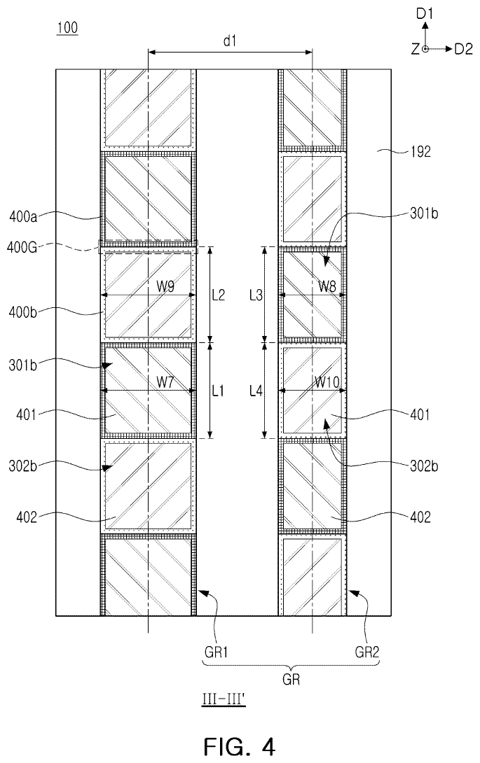

FIG. 3A is an enlarged view of region ‘A’ of FIG. 2A, FIG. 3B is an exploded perspective view of upper portions of the guard ring structures GR of FIG. 3A, and FIG. 4 is a cross-sectional view of the guard ring structure of FIG. 3A taken along plane III-III′.

Referring to FIGS. 2B and 3B, each of the inner guard ring structure GR1 and the outer guard ring structure GR2 may include a first structure 301 and a second structure 302.

Referring to FIG. 3B, a direction perpendicular to the Z-direction and in which the guard ring structures GR extend in the X-Y plane may be defined as the D1 direction (e.g., the second direction). Additionally, on the X-Y plane, as a width direction of the guard ring structure GR, a direction perpendicular to the D1 direction (e.g., the second direction) may be defined as the D2 direction (e.g., the third direction).

As described above, the inner guard ring structure GR1 and the outer guard ring structure GR2 have the same vertical structure shape except for a difference in an extension length and a width, and the inner guard ring structure GR1 will be described in detail first.

The inner guard ring structure GR1 may be understood as a first structure 301 and a second structure 302 extending in the Z-direction to form a single protective wall, and may form a closed-loop wall structure.

The first structure 301 may include a first body portion 301a and first protrusion portions 301b protruding from the first body portion 301 a.

The first body portion 301a may have an upper surface S3 that continuously penetrates through the semiconductor substrate 101 and the cell region insulating layer 190, and is coplanar with an upper surface of the cell region insulating layer 190, a lower surface connected to an upper end of the peripheral guard ring structure GRp, and a side surface between the upper surface S3 and the lower surface.

The first body portion 301a may occupy most of an entire length of the inner guard ring structure GR1 and may have a first height h1 in the Z-direction.

Since the first body portion 301a has a closed loop shape similar to a planar shape of the inner guard ring structure GR1, the first body portion 301a may be a wall structure having a short width in the D2 direction perpendicular to the D1 direction, which is the extension direction. An upper surface S3 of the first body portion 301 a may have a first width w1, the first width w1 may be greater than a width of a lower surface of the first body portion 301a, and the first body portion 301a may have an inclined side surface according to a width difference between the upper surface S3 and the lower surface. A side surface of the first body portion 301a may have a bent portion, but is not limited thereto, and may have a continuous inclination.

The first structure 301 may include a plurality of first protrusion portions 301b protruding upwardly from the upper surface S3 of the first body portion 301a. The first protrusion portions 301b may have a second height h2 in the vertical direction and may be spaced apart from one another in the D1 direction. A separation space between the first protrusion portions 301b is a first recess portion G1, and the first recess portions G1 are regions filled by the second structure 302 when viewed from the perspective of the first structure 301, and may be defined as a space surrounded by the first body portion 301a and the first protrusion portions 301b.

Each of the first protrusion portions 301b may have the same vertical length, the same extension length, and the same width, and the first recess portions G1 may also have the same recessed length.

Each of the first protrusion portions 301b may be disposed to penetrate through the first upper insulating layer 192, and may include an upper surface S1 and a lower surface, and a side surface between the upper surface S1 and the lower surface.

A width w3 of the upper surface S1 of the first protrusion portions 301b may be greater than a width of the lower surface, and the first protrusion portions 301b may have an inclined side surface according to the width of the upper surface S1 and the lower surface. Accordingly, side surfaces of the first protrusion portions 301b may have an inclination(⊖1) so as to have a positive value with respect to lower surfaces of the first protrusion portions 301b. In this case, having the inclination(⊖1) as the positive value does not refer to having an inclination of one side surface, but may be defined as increasing a distance between opposing side surfaces in a direction away from the first body portion 301a, that is, increasing a cross-sectional area as the side surface goes from the lower surface to the upper surface S1. In this case, the width w3 of the upper surface S1 of the first protrusion portions 301b may be less than the first width w1 of the first body portion 301a.

A length of the upper surface S1 of each of the first protrusion portions 301b in the D1 direction and a length of the lower surface S1 of each of the first recess portions G1 in the D1 direction may be substantially the same. Accordingly, in the plan view of FIG. 4, obtained by cutting the first protrusion portions 301b on the central level in the Z-direction, a length L1 of the first protrusion portion 301b in the D1 direction may be substantially the same as a length of the first recess portion G1 in the D1 direction.

The first structure 301 may include a first diffusion barrier 400a and a first metal layer 401 for the first body portion 301a and the first protrusion portions 301b. The first diffusion barrier 400a may cover a side surface and a lower surface of the first body portion 301a and side surfaces of the first protrusion portions 301b. The first metal layer 401 may be disposed on the first diffusion barrier 400a.

According to example embodiments, the first diffusion barrier 400a may include titanium nitride (TiN) or TSN (Ti—Si—N).

According to example embodiments, the first metal layer 401 may include at least one of a conductive material, for example, tungsten (W), copper (Cu), aluminum (Al) or alloys thereof.

The second structure 302 may include a second body portion 302a and second protrusion portions 302b protruding from a lower surface S4 of the second body portion 302a.

The second body portion 302a may have an upper surface penetrating the second upper insulation layer 194 and forming a coplanar surface with an upper surface of the second upper insulation layer 194, a lower surface S4 forming a coplanar surface with an upper surface of the first upper insulation layer 192, and a side surface between the upper surface and the lower surface S4.

The second body portion 302a may have a shape similar to that of the first body portion 301a, and specifically, a width w5 of an upper surface of the second body portion 302a may be greater than a width of the lower surface S4 of the second body portion 302a, and the second body portion 302a may have an inclined side surface according to a difference in width between the upper surface and the lower surface S4. The side surface of the second body portion 302a may have a continuous inclination. The width w5 of the upper surface of the second body portion 302a may be greater than a width of upper ends of the second protrusion portions 302b. The width w5 of the upper surface of the second body portion 302a may be greater than the width w3 of the upper surface S1 of the first protrusion portion 301b, and may be less than the first width w1 of the first body portion 301a.

The second body portion 302a may have a fourth height h4 in the Z-direction, and a first height h1 of the first body portion 301a may be greater than the fourth height h4 of the second body portion 302a.

The second structure 302 may include a plurality of second protrusion portions 302b protruding downwardly from the lower surface S4 of the second body portion 302a. The second protrusion portions 302b may be spaced apart from one another in the D1 direction. A separation space between the second protrusion portions 302b is a second recess portion G2, and the second recess portions G2 is a region filled by the first protrusion portions 301b when viewed from the perspective of the second structure 302, and may be defined as a space surrounded by the second body portion 302a and the second protrusion portions 302b.

Each of the second protrusion portions 302b may have the same vertical length, the same extension length and the same width, and the second recess portions G2 may also have the same recessed length.

Each of the second protrusion portions 302b may be disposed to penetrate through the first upper insulating layer 192, and may include an upper surface and a lower surface S2, and a side surface between the upper surface and the lower surface S2.

The second protrusion portions 302b may have a third height h3 in the Z-direction and may be equal to the second height h2 of the first protrusion portions 301b in the Z-direction.

Each of the second protrusion portions 302b may have a width of an upper end less than a width of the lower surface S2 and may have an inclined side surface according to the width of the upper surface and the lower surface S2. Accordingly, the side surface of the second protrusion portions 302b may have an inclination(⊖2) so as to have a negative value with respect to the lower surface S2 of the second protrusion portion 302b. In this case, having the inclination(⊖2) as the negative value does not refer to having an inclination of one side surface, but may be defined as increasing a distance between opposing side surfaces in a direction away from the second body portion 302a, that is, increasing a cross-sectional area as the side surface goes from the upper surface to the lower surface S2.

A length of the upper surface of each of the second protrusion portions 302b in the D1 direction and a length of the lower surface of each of the second recess portions G2 in the D1 direction may be substantially the same. Accordingly, in the plan view of FIG. 4, obtained by cutting the second protrusion portions 302b on the central level in the Z-direction, a length L2 of the second protrusion portion 302b in the D1 direction may be substantially the same as a length of the second recess portion G2 in the D1 direction.

The second structure 302 may include a second diffusion barrier 400b and a second metal layer 402 for the second body portion 302a and the second protrusion portions 302b.

The second diffusion barrier 400b may cover the side surface and the lower surface S4 of the second body portion 302a and the side surface and the lower surface S2 of the second protrusion portions 302b. The second metal layer 402 may be disposed on the second diffusion barrier 400b.

According to example embodiments, the second diffusion barrier 400b may include titanium nitride (TiN) or TSN (Ti—Si—N). The second diffusion barrier 400b may include a different material from the first diffusion barrier 400a, but the present disclosure is not limited thereto. According to example embodiments, the second metal layer 402 may include the same material as the first metal layer 401, and may include at least one of a conductive material, and may include, for example, tungsten (W), copper (Cu), aluminum (Al), and alloys thereof.

As illustrated in FIGS. 3B and 4, the first upper insulating layer 192 may be penetrated, and the second protrusion portions 302b may fill the first recess portions G1, and the first protrusion portions 301b may fill the second recess portions G2. The side surfaces of the first protrusion portions 301b and the second protrusion portions 302b may be disposed to contact one another.

Accordingly, each of the second protrusion portions 302b of the second structure 302 may be disposed within the first recess portions G1, and the first protrusion portions 301b may be disposed within the second recess portions G2, so that the first protrusion portions 301b and the second protrusion portions 302b may be disposed alternately in the D1 direction on the upper surface S1 of the first body portion 301a.

On the plane of FIG. 4 cut at a center height of the first protrusion portion 301b and the second protrusion portion 302b, when lengths of the second protrusion portion 302b and the second recess portion G2 in the D1 direction are equal to one another, and the first protrusion portion 301b is disposed within the second recess portion G2, the first length L1 of the first protrusion portion 301b in the D1 direction and the second length L2 of the second protrusion portion 302b in the D1 direction may be disposed to have the same length.

At least a portion of the upper surface S1 of the first protrusion portions 301b may be in contact with at least a portion of the lower surface S4 of the second body portion 302a, and at least a portion of the lower surface S2 of the second protrusion portions 302b may be in contact with at least a portion of the upper surface S3 of the first body portion 301a, but the present disclosure is not limited thereto. Accordingly, the first structure 301 and the second structure 302 may be wedge-bonded to one another to form a single wall structure.

Accordingly, the first diffusion barrier 400a or the second diffusion barrier 400b may be disposed along a boundary surface between the first structure 301 and the second structure 302, and a boundary between the first protrusion portion 301b and the second protrusion portion 302b. Additionally, both the first and second diffusion barriers 400a and 400b may be disposed on a bonded surface 400G of the first protrusion portion 301b and the second protrusion portion 302b.

Accordingly, the diffusion barriers 400a and 400b on the bonded surface 400G of the first protrusion portion 301b and the second protrusion portion 302b may have a greater thickness than the other boundary surfaces.

Meanwhile, the semiconductor device 100 may surround the inner guard ring structure GR1 and further include an outer guard ring structure GR2 in the edge region C2. As described above, the outer guard ring structure GR2 may have a structure similar to the inner guard ring structure GR1 as a whole, and it may be understood that a width thereof in the third direction (e.g., the D2 direction) is less than that of the inner guard ring structure GR1.

Specifically, the outer guard ring structure GR2 includes a first structure 301 and a second structure 302.

The first structure 301 may include a first body portion 301a, first protrusion portions 301b, and first recess portions G1 between the first protrusion portions 301b.

The second structure 302 may include a second body portion 302a, second protrusion portions 302b, and second recess portions G2 between the second protrusion portions 302b.

In the outer guard ring structure GR2, the upper surface S3 of the first body portion 301 a may have a second width w2, and the second width w2 may be less than the first width w1 of the inner guard ring structure GR1.

A width w6 of the upper surface of the second body portion 302a may be greater than a width of upper ends of the second protrusion portions 302b. The width w6 of the upper surface of the second body portion 302a may be greater than the width of the upper ends of the second protrusion portions 302b. The width w6 of the upper surface of the second body portion 302a may be greater than a width w4 of the upper surface S1 of the first protrusion portions 301b and less than the second width w2 of the first body portion 301a.

Similarly to the inner guard ring structure GR1, the second recess portions G2 may be disposed between the second protrusion portions 302b in the D1 direction, and the second protrusion portions 302b may fill the first recess portions G1, and the first protrusion portions 301b may fill the second recess portions G2.

Accordingly, each of the second protrusion portions 302b of the second structure 302 may be disposed within the first recess portions G1, and the first protrusion portions 301b may be disposed within the second recess portions G2, so that the first protrusion portions 301b and the second protrusion portions 302b may be disposed alternately in the D1 direction on the first body portion 301a (see FIG. 3B).

Referring to FIG. 4, on a plane obtained by cutting, on an intermediate level, the lengths of the first and second protrusion portions 301b and 302b in the Z-direction, the first protrusion portion 301b may have a third length L3 in the D1 direction, and the third length L3 may be equal to a length of the first recess portion G1 in the D1 direction. The second protrusion portion 302b may have a fourth length LA in the D1 direction, and the fourth length L4 may be equal to the length of the second recess portion G2 in the D1 direction.

In the outer guard ring structure GR2, the third length L3 of the first protrusion portion 301b and the fourth length LA of the second protrusion portion 302b may be disposed to have the same length.

As illustrated in FIG. 4, the inner guard ring structure GR1 and the outer guard ring structure GR2 may have different arrangement structures.

Specifically, in the inner guard ring structure GR1 and the outer guard ring structure GR2, the second protrusion portions 302b may be disposed to be offset in the D2 direction. Accordingly, the second protrusion portions 302b of the inner guard ring structure GR1 may be disposed to align with the first protrusion portions 301b of the outer guard ring structure GR2 in the D2 direction, and the first protrusion portions 301b of the inner guard ring structure GR1 may be disposed to align with the second protrusion portions 302b of the outer guard ring structure GR2 in the D2 direction.

Accordingly, after forming an opening in a region corresponding to the first protrusion portions 301b on in an upper portion of the first structure 301, when a portion of the first upper insulating layer 192 remains in the first recess portion G1 to open a region corresponding to the first body portion 301a through the opening, a portion of the first upper insulating layer 192 may remain in a lattice shape on an elongated opening that is long in a vertical direction corresponding to the first body portion 301a and also long in an extension direction, the opening of the first body portion 301a may be prevented from being tilted.

Accordingly, when forming an outer guard ring structure GR2 concentrically in proximity to the inner guard ring structure GR1, even when two adjacent elongated openings are formed, the process may be advanced while securing structural stability by having a lattice-shaped support structure on an upper portion thereof.

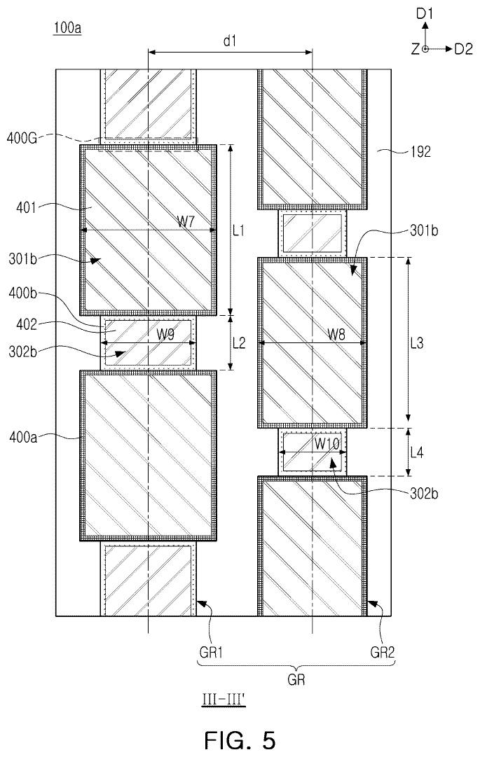

Hereinafter, with reference to FIGS. 5 to 7, various example embodiments of the arrangement of the first and second protrusion portions 301b and 302b of the inner guard ring structure GR1 and the outer guard ring structure GR2 will be described.

FIGS. 5 to 7 are plan views of guard ring structures GR of a semiconductor device according to example embodiments. FIGS. 5 to 7 illustrate planes obtained by cutting the first protrusion portion 301b and the second protrusion portion 302b on an intermediate level in the Z-direction, as in FIG. 4.

A guard ring structure GR of a semiconductor device 100a of FIG. 5 is the same as the guard ring structure GR of FIG. 4, except that lengths and widths of the first protrusion portions 301b are greater than those of the second protrusion portions 302b.

The first length L1 of the first protrusion portions 301b may have a multiple greater than 1 of the second length L2 of the second protrusion portions 302 b, and may be, for example, an integer multiple greater than 1 of the second length L2 of the second protrusion portions 302 b, and may have 3 to 4 times the second length L2 of the second protrusion portions 302b.

In the inner guard ring structure GR1, a width w7 of the first protrusion portion 301b may be greater than a width w9 of the second protrusion portion 302b.

Similarly to the inner guard ring structure GR1, the outer guard ring structure GR2 may have a third length L3 of the first protrusion portions 301b that is an integer multiple of the fourth length L4 of the second protrusion portion 302b.

In the outer guard ring structure GR2, a width w8 of the first protrusion portion 301b may be greater than a width w10 of the second protrusion portion 302b.

In this manner, the first protrusion portions 301b of the inner and outer guard ring structures GR may be disposed to have a greater width and length than the second protrusion portions 302b.

The second protrusion portions 302b of the inner and outer guard ring structures GR may be offset from one another at least in the D2 direction, but the present disclosure is not limited thereto. All of the second protrusion portions 302b of the inner guard ring structure GR1 may overlap the first protrusion portions 301b of the outer guard ring structure GR2 in the D2 direction.

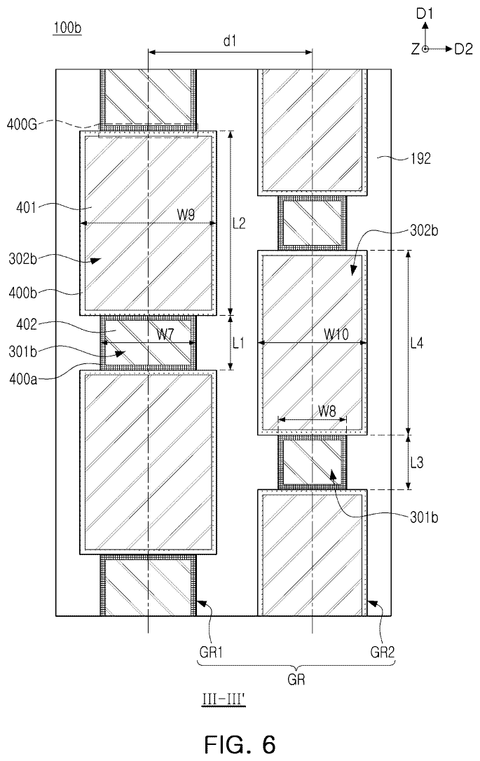

Guard ring structures GR of a semiconductor device 100b of FIG. 6 are identical to the guard ring structures GR of FIG. 4, except that the length and width of the second protrusion portions 302b are greater than those of the first protrusion portions 301b.

The second length L2 of the second protrusion portions 302b may be greater than the first length L1 of the first protrusion portions 301b, and may be an integer multiple greater than 1 of the first protrusion portions 301 b, and may be, for example, 3 to 4 times greater the first protrusion portions 301b.

In the inner guard ring structure GR1, the width w9 of the second protrusion portion 302b may be greater than the width w7 of the first protrusion portion 301b.

Similarly to the inner guard ring structure GR1, the outer guard ring structure GR2 may also have the fourth length L4 of the second protrusion portions 302b that may be an integer multiple of the third length L3 of the first protrusion portions 301b.

In the outer guard ring structure GR2, the width w10 of the second protrusion portion 302b may be greater than the width w8 of the first protrusion portion 301b.

The second protrusion portions 302b of the inner and outer guard ring structures GR may be offset from one another in the D2 direction, and all of the second protrusion portions 302b of the inner guard ring structure GR1 may overlap the first protrusion portions 301b of the outer guard ring structure GR2 in the D2 direction.

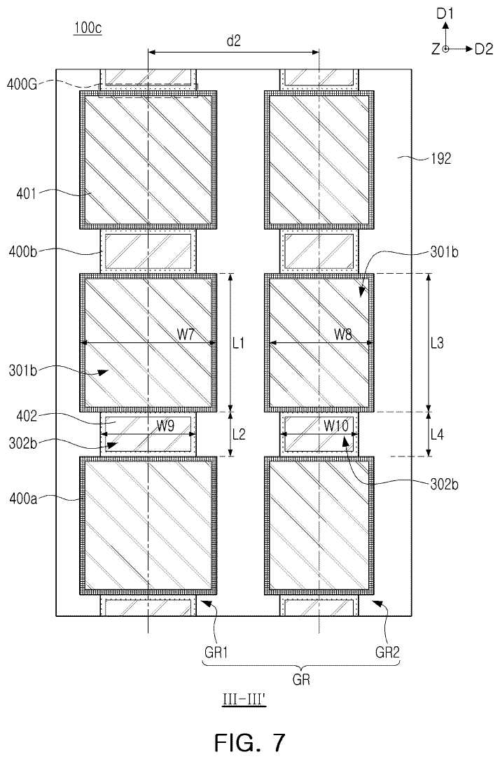

Guard ring structures GR of a semiconductor device 100c of FIG. 7 are the same as the guard ring structure of FIG. 4, except that a length and a width of the first protrusion portions 301b may be greater than or equal to those of the second protrusion portions 302b, and the inner and outer second protrusion portions 302b overlap one another in the D2 direction.

The first length L1 of the first protrusion portions 301b may be greater than or equal to the second length L2 of the second protrusion portions 302b, and may be, for example, an integer multiple greater than 1 of the second length L2 of the second protrusion portions 302 b, and may be 3 to 4 times the second length L2 of the second protrusion portions 302b.

In the inner guard ring structure GR1, the width w7 of the first protrusion portion 301b may be greater than or equal to the width w9 of the second protrusion portion 302b.

Similarly to the inner guard ring structure GR1, in the outer guard ring structure GR2, the third length L3 of the first protrusion portions 301b may be equal to or an integer multiple of the fourth length L4 of the second protrusion.

In the outer guard ring structure GR2, the width w8 of the first protrusion portion 301b may be greater than or equal to the width w10 of the second protrusion portion 302b.

The first protrusion portions 301b of the inner guard ring structure GR1 may overlap the first protrusion portions 301b of the outer guard ring structure GR2 in the D2 direction, respectively.

Specifically, the first protrusion portions 301b of the inner guard ring structure GR1 may be disposed to align with the first protrusion portions 301b of the outer guard ring structure GR2 in the D2 direction, and the second protrusion portions 302b of the inner guard ring structure GR1 may be disposed to align with the second protrusion portions 302b of the outer guard ring structure GR2 in the D2 direction.

Accordingly, a distance d2 from a centerline of the inner guard ring structure GR1 to a centerline of the outer guard ring structure GR2 in FIG. 7 may be greater than a distance d1 from the centerline of the inner guard ring structure GR1 to the centerline of the outer guard ring structure GR2.

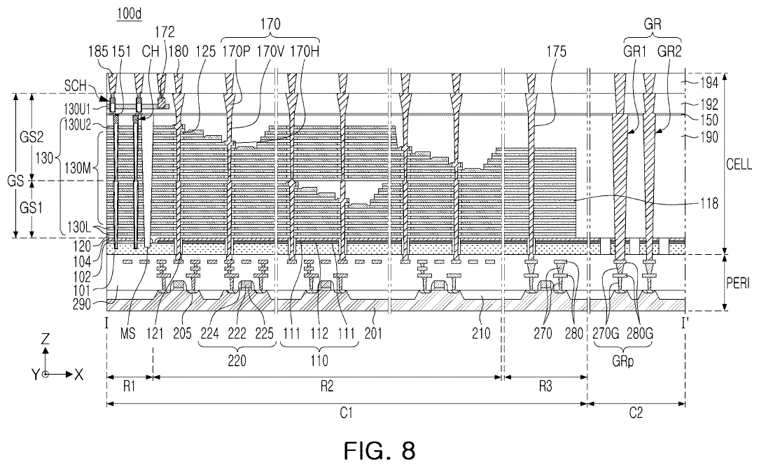

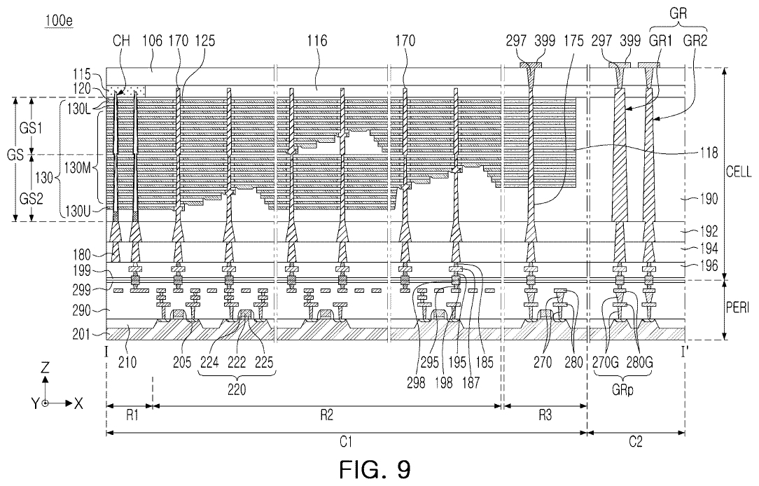

FIGS. 8 and 9 are schematic cross-sectional views of a semiconductor device according to example embodiments.

A semiconductor device 100d of FIG. 8 is the same as the semiconductor device 100 of FIGS. 1 to 4, except that the semiconductor device 100d includes second channel structures SCH on the channel structures CH.

The second channel structures SCH may extend in the Z-direction by penetrating through the first upper gate electrode 130U1 and may be connected to the channel structures CH, respectively. The second channel structures SCH may be respectively disposed on the channel structures CH and may be disposed to be shifted in a horizontal direction from the channel structures CH, but the present disclosure is not limited thereto.

A horizontal insulating layer 150 may be disposed between the channel structures CH and the second channel structures SCH, and may extend horizontally in the first to third regions R1, R2 and R3. The horizontal insulating layer 150 may be disposed between the first upper gate electrode 130U1 and a second upper gate electrode 130U2. The horizontal insulating layer 150 may be used as an etching stop layer when forming the second channel structures SCH, and may also be a layer used when forming connection pads 151.

The horizontal insulating layer 150 includes an insulating material and may include a different material from the second and third cell region insulating layers 194 and 196. The horizontal insulating layer 150 may be a hydrogen blocking layer and may include a material blocking or reducing diffusion of hydrogen (H). The horizontal insulating layer 150 may include a nitride and may include, for example, at least one of SiN, SiON, SiCN, or SiOCN

The connection pads 151 may penetrate through the horizontal insulating layer 150 between the channel structures CH and the second channel structures SCH to electrically connect first channel layers and second channel layers. The connection pads 151 may be formed by removing a portion of the horizontal insulating layer 150, and may have upper surfaces that are coplanar with an upper surface of the horizontal insulating layer 150. The connection pads 151 may be disposed in a form in which the first channel pads are partially recessed. However, the specific arrangement form of the connection pads 151 may be variously changed in example embodiments. The connection pads 151 may include a conductive material, and may include, for example, polycrystalline silicon.

The second channel structures SCH may extend in the Z-direction by penetrating through the first upper gate electrodes 130U1 and may be connected to the channel structures CH, respectively. The second channel structures SCH may be disposed on the channel structures CH, respectively, and may be disposed shifted in the horizontal direction from the channel structures CH, but the present disclosure is not limited thereto.

Each of the second channel structures SCH may include a second channel layer, a second gate dielectric layer, a second channel buried insulating layer, and a second channel pad, which are disposed within the upper channel hole. The second channel layer may be formed in an annular shape surrounding the second channel buried insulating layer inside. The second channel layer may be connected to a connection pad 151 in a lower portion, and may be electrically connected to the first channel layer of the channel structure CH through the connection pad 151.

The description of the first channel layer, the first gate dielectric layer, the first channel buried insulating layer, and the first channel pad described above may be equally applied to the description of the materials of the second channel layer, the second gate dielectric layer, the second channel buried insulating layer and the second channel pad.

The second channel structure SCH and the first upper gate electrode 130U1 may be disposed to overlap the first upper insulating layer 192 in the horizontal direction. That is, the first upper insulating layer 192 may be disposed on the cell region insulating layer 190 and the horizontal insulating layer 150 by covering the first upper gate electrode 130U1 and the second channel structure SCH.

Referring to FIG. 9, a semiconductor device 100e may include a first semiconductor structure PERI and a second semiconductor structure CELL bonded by a wafer bonding method.

The description of the peripheral circuit region PERI described above with reference to FIG. 2a may be applied to the first semiconductor structure PERI. However, the first semiconductor structure PERI may further include first bonding vias 295, first bonding metal layers 298, and first bonding insulating layer 299, which is included in a bonding structure. The first bonding vias 295 may be disposed in an upper portion of circuit interconnection lines 280 and may be connected to the circuit interconnection lines 280. At least some of the first bonding metal layers 298 may be connected to the first bonding vias 295 on the first bonding vias 295. The first bonding metal layers 298 may be connected to second bonding metal layers 198 of the second semiconductor structure CELL. The bonding metal layers 298 may provide an electrical connection path according to the bonding of the first semiconductor structure PERI and the second semiconductor structure CELL together with the second bonding metal layers 198. Some of the first bonding metal layers 298 may not be connected to lower circuit interconnection lines 280 and may be disposed only for bonding. The first bonding vias 295 and the first bonding metal layers 298 may include a conductive material, and may include, for example, copper (Cu). The first bonding insulating layer 299 may be disposed around the first bonding metal layers 298. The first bonding insulating layer 299 may also function as a diffusion barrier layer for the first bonding metal layers 298, and may include, for example, at least one of SiN, SiON, SiCN, SiOC, SiOCN, or SiO.

The description of the memory cell region CELL described above with reference to FIG. 2A may be applied to the second semiconductor structure CELL, unless otherwise described. The second semiconductor structure CELL may further include cell interconnection lines 187, which is included in a cell interconnection structure, and may further include second bonding vias 195, second bonding metal layers 198, and a second bonding insulating layer 199, which are included in the bonding structure. In the second semiconductor structure CELL, a conductive pattern layer 115 covering an upper end of the channel structure without a source structure may be disposed.

In the channel structure, a channel dielectric structure may be removed from an upper end thereof to expose the channel layer, and a conductive pattern layer in direct contact with the exposed channel layer may be disposed.

The conductive pattern layer 115 may be doped polysilicon, but is not limited thereto, and may function as a common source line.

A passivation layer 106 covering an upper surface of the conductive pattern layer 115 may be further included.

The passivation layer 106 may protect the semiconductor device 100e. The passivation layer 106 may include at least one of an insulating material, for example, silicon oxide, silicon nitride, or silicon carbide.

Third vias 297 may be disposed on the through-contact plug 175 and the guard ring structure GR, and the vias may be connected to a pad structure 399 exposed upwardly by penetrating through the substrate insulating layer 116 and the passivation layer 106. The third vias 297 may include a conductive material, and may include, for example, copper (Cu).

The cell interconnection lines 187 may be connected to the studs 180. However, in example embodiments, the number of layers and the arrangement form of plugs and interconnection lines included in the cell interconnection structure may be variously changed. The cell interconnection lines 187 may be formed of a conductive material, and may include, for example, at least one of tungsten (W), aluminum (Al), or copper (Cu).

The second bonding vias 195 and the second bonding metal layers 198 may be disposed below the cell interconnection lines 187. The second bonding vias 195 connect the cell interconnection lines 187 and the second bonding metal layers 198, and the second bonding metal layers 198 may be bonded to the first bonding metal layers 298 of the first semiconductor structure PERI. The second bonding insulating layer 199 may be bonded and connected to the first bonding insulating layer 299 of the first semiconductor structure PERI. The second bonding vias 195 and the second bonding metal layers 198 may include a conductive material, for example, copper (Cu). The second bonding insulating layer 199 may include, for example, at least one of SiO, SiN, SiCN, SiOC, SiON, or SiOCN.

The first and second semiconductor structures PERI and CELL may be bonded by bonding the first bonding metal layers 298 and the second bonding metal layers 198 and bonding the first bonding insulating layer 299 and the second bonding insulating layer 199. The bonding of the first bonding metal layers 298 and the second bonding metal layers 198 may be, for example, copper (Cu)-to-copper (Cu) bonding, and the bonding of the first bonding insulating layer 299 and the second bonding insulating layer 199 may be, for example, dielectric-to-dielectric bonding, such as SiCN-to-SiCN bonding. The first and second semiconductor structures PERI and CELL may be bonded by hybrid bonding including copper (Cu)-to-copper (Cu) bonding and dielectric-to-dielectric bonding.

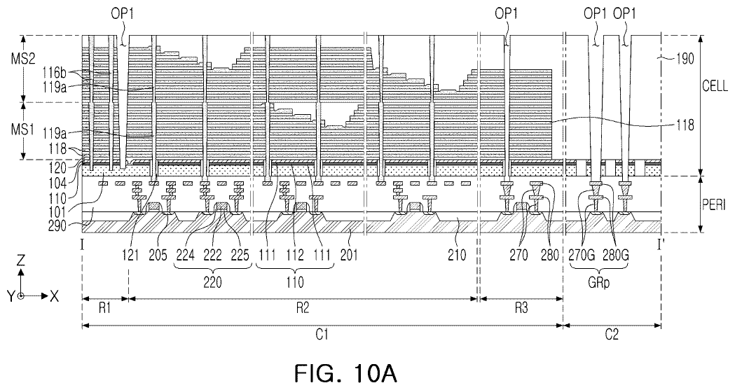

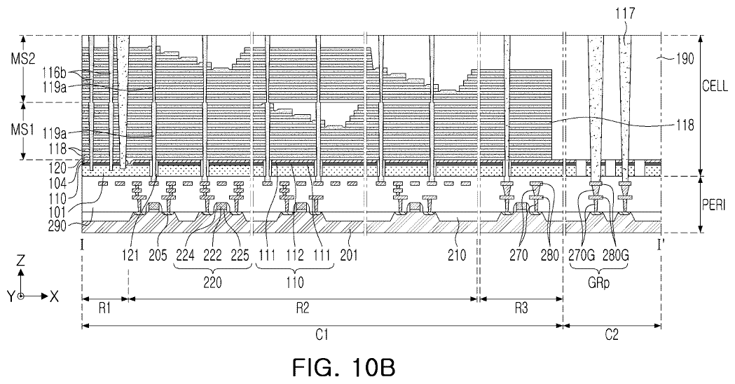

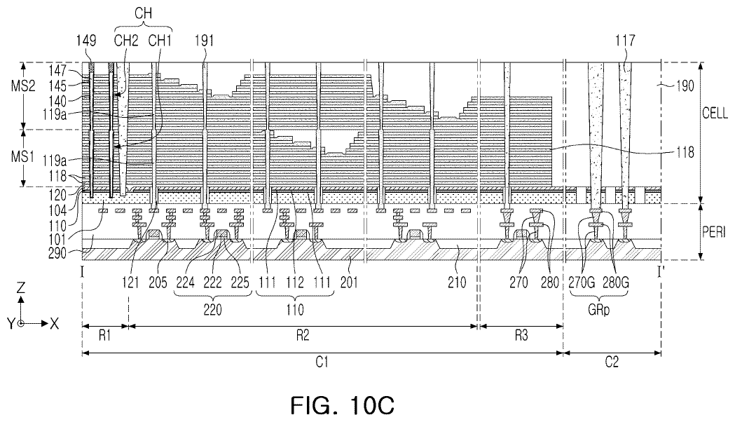

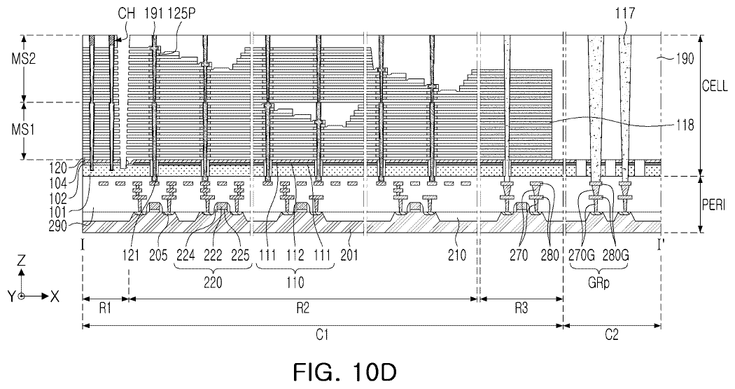

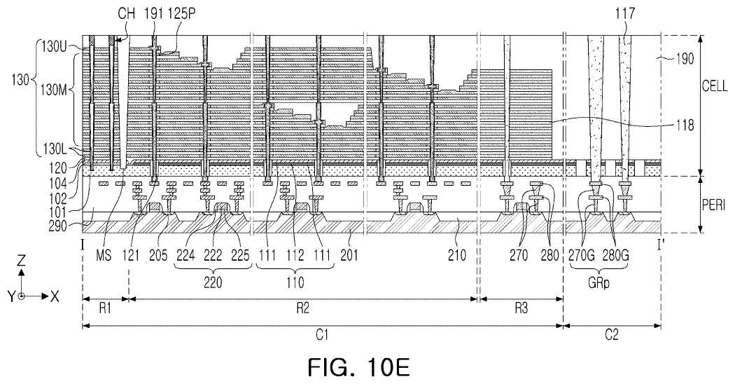

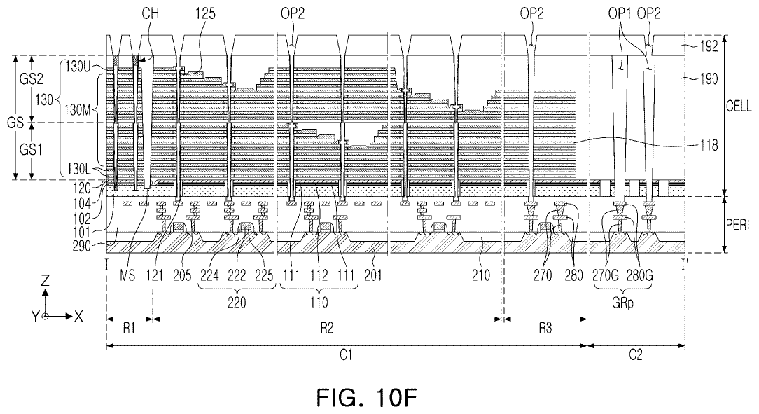

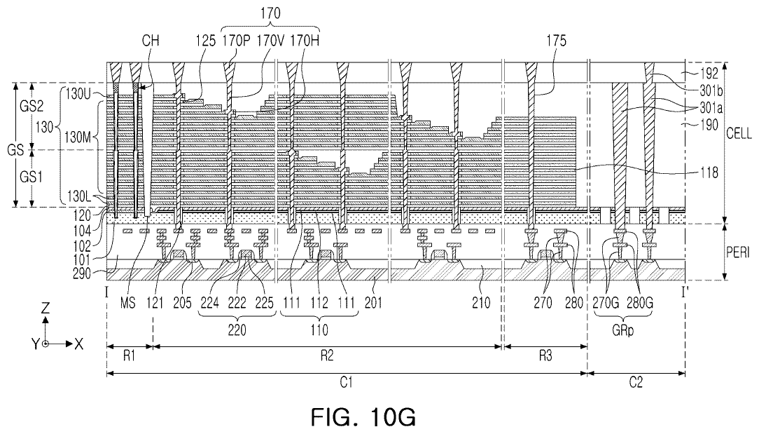

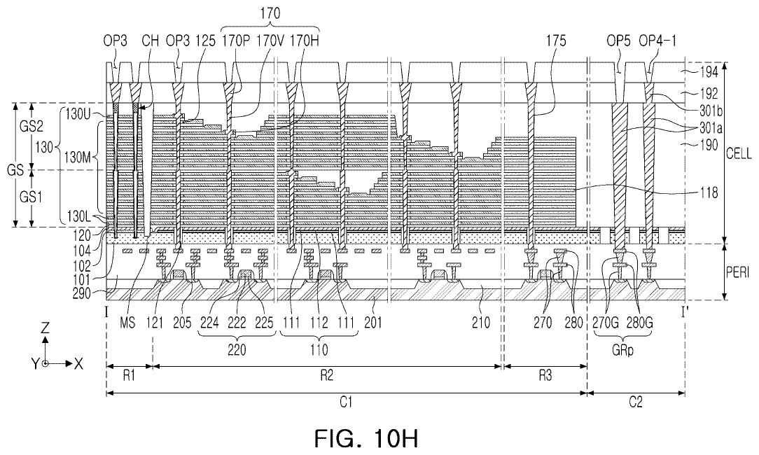

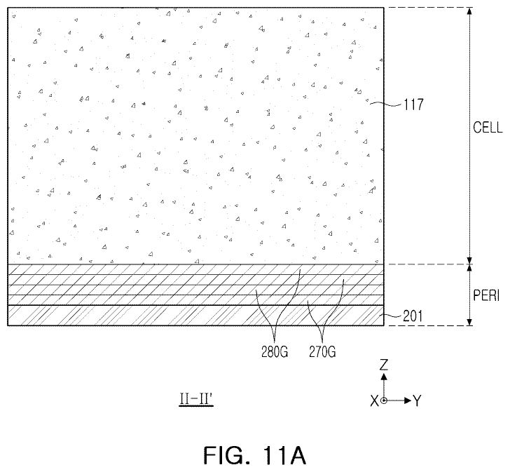

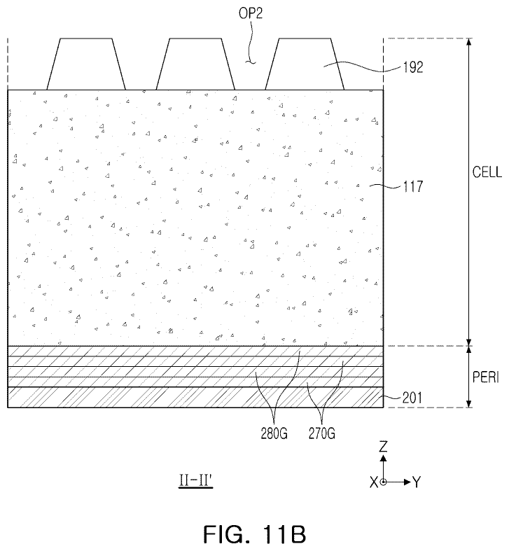

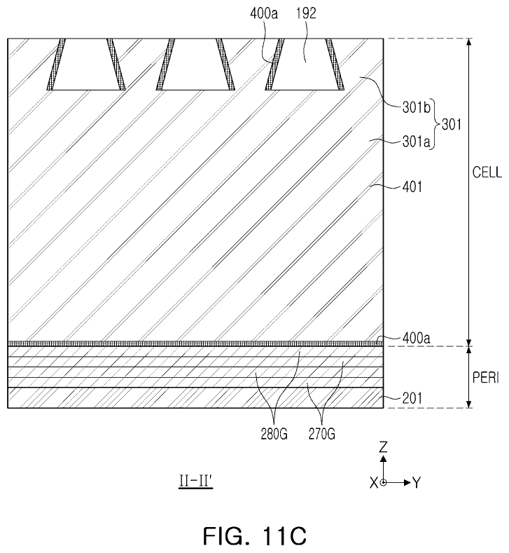

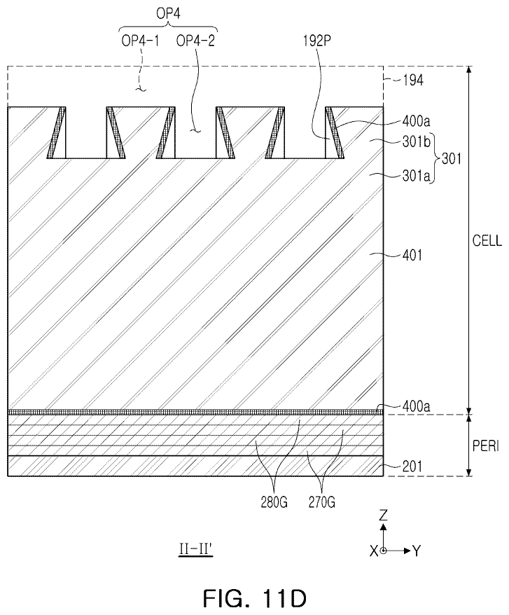

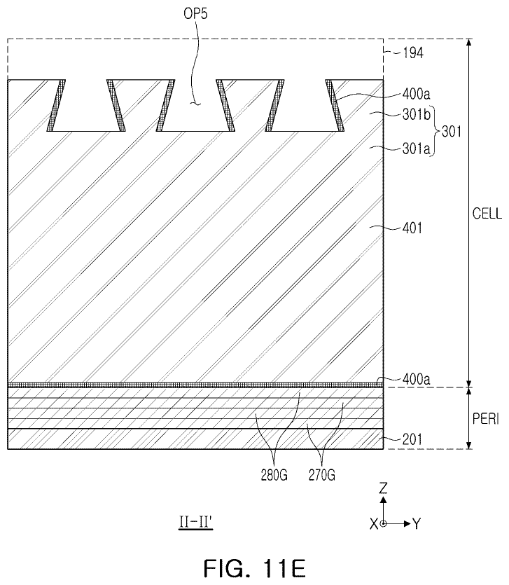

FIGS. 10A to 10H, and 11A to 11E are schematic cross-sectional views illustrating a method of manufacturing a semiconductor device according to example embodiments.

FIGS. 10A to 10K each illustrate a region corresponding to FIG. 2A, and FIGS. 11A to 11E each illustrate a region corresponding to FIG. 2B.

Referring to FIG. 10A, first openings OP1 may be formed to partially penetrate through the mold structure and the cell region insulating layer 190 in the first direction.

Before the first openings OP1 are formed, circuit elements 220, circuit interconnection structures and peripheral region insulating layers 290, which are included in a peripheral circuit region PERI, may be formed on the substrate 201.

Element isolation layers 210 may be formed within the substrate 201, and a circuit gate dielectric layer 222 and a circuit gate electrode 225 may be sequentially formed on the substrate 201. The element isolation layers 210 may be formed, for example, by a shallow trench isolation (STI) process. The circuit gate dielectric layer 222 and the circuit gate electrode 225 may be formed using atomic layer deposition (ALD) or chemical vapor deposition (CVD). The circuit gate dielectric layer 222 may be formed of silicon oxide, and the circuit gate electrode 225 may be formed of at least one of polycrystalline silicon or a metal silicide layer, but the present disclosure is not limited thereto. Next, a spacer layer 224 and impurity regions 205 may be formed on both sidewalls of the circuit gate dielectric layer 222 and the circuit gate electrode 225. According to example embodiments, the spacer layer 224 may be formed of a plurality of layers. The impurity regions 205 may be formed by performing an ion implantation process.

Among the above circuit interconnection structures, the circuit contact plugs 270 may be formed by partially forming a peripheral region insulating layer 290, etching and removing a portion thereof, and filling the removed part with a conductive material. The circuit interconnection lines 280 may be formed, for example, by depositing a conductive material and then patterning the conductive material.

The peripheral region insulating layer 290 may be formed of a plurality of insulating layers. The peripheral region insulating layer 290 may be a portion in each operation of forming the circuit interconnection structure. Accordingly, a peripheral circuit region PERI may be formed.

On the peripheral circuit region PERI, a semiconductor substrate 101 in which a memory cell region CELL is provided, a horizontal sacrificial layer 110, a second horizontal conductive layer 104, and substrate insulating layers 121 may be formed.

Next, a first mold structure MS1 of the mold structure may be formed, and first channel sacrificial layers 116a and first contact sacrificial layers 119a penetrating through the first mold structure MS1 may be formed.

The first mold structure MS1 may be formed on the second horizontal conductive layer 104 and the substrate insulating layers 121 at a height at which a first stack structure GS1 (see FIG. 2A) is disposed.

The sacrificial insulating layers 118 may be layers in which at least a portion thereof is replaced with a portion of the gate electrodes 130 (see FIG. 2A) through a subsequent process. The sacrificial insulating layers 118 may be formed of a different material from the interlayer insulating layers 120, and may be formed of a material that may be etched with etching selectivity under specific etching conditions with respect to the interlayer insulating layers 120.

Next, a first cell region insulating layer 192 covering the first mold structure MS1 may be formed. The first channel sacrificial layers 116a may be formed in positions corresponding to the channel structures CH (see FIG. 2A) in the first region R1. The first contact sacrificial layers 119a may be formed in positions corresponding to the contact plugs 170 (see FIG. 2A) in the second region R2. The first channel sacrificial layers 116a and the first contact sacrificial layers 119a may be formed simultaneously.

The first channel sacrificial layers 116a and the first contact sacrificial layers 119a may include, for example, at least one of TiN or polycrystalline silicon.

A second mold structure MS2, second channel sacrificial layers 116b and second contact sacrificial layers 119b may be formed on the first mold structure MS1 in the same manner as the first mold structure MS1, the first channel sacrificial layers 116a, and the first contact sacrificial layers 119a, respectively. Next, a cell region insulating layer 190 may be formed in an edge region C2 surrounding the mold structures MS1 and MS2.

A first opening OP1 may be formed in each region in which the guard ring structure is disposed, by penetrating through the semiconductor substrate 101 from the upper surface of the cell region insulating layer 190. The first opening OP1 may have a shape corresponding to the first body portions 301a of FIG. 2A, may surround the mold structures, and may be formed in a closed-loop shape.

In this case, a separation opening may be formed together in a region forming the separation region MS.

The first opening OP1 may be formed without a bended portion on a side surface thereof, but the present disclosure is not limited thereto, and when the cell region insulating layer 190 is formed of multiple layers, the first opening OP1 may be formed multiple times, and when the first opening OP1 is formed multiple times, the bent portion may be formed on the side surface of the first opening OP1.

Referring to FIG. 10B, in the first openings OP, a sacrificial layer may be formed in a position corresponding to the through-contact plug 175 and the guard ring structure GR (see FIG. 2A). Accordingly, as in FIG. 11A, a sacrificial guard ring structure 117 penetrating through the cell region insulating layer 190 and the semiconductor substrate 101 in the first direction and surrounding the mold structure may be formed. The sacrificial layer may include materials such as carbon, silicon, or the like, as in vertical sacrificial structures.

Referring to FIG. 10C, a channel structure may be formed in the first region R1. The channel structures CH may be formed by removing the first and second channel sacrificial layers 116a and 116b to form lower channel holes, and then, sequentially depositing at least a portion of the first gate dielectric layer, the first channel layer, the first channel buried insulating layer, and the first channel pad, within the lower channel holes.

The first gate dielectric layer may be formed to have a uniform thickness using an ALD or CVD process. In this operation, the first gate dielectric layer may be formed entirely or partially, and a portion extending vertically along the channel structures CH to the semiconductor substrate 101 may be formed in this operation. The first channel layer may be formed on the first gate dielectric layer within the lower channel holes. The first channel buried insulating layer may be formed to fill the lower channel holes and may be formed of an insulating material. The first channel pad may be formed of a conductive material, and may, for example, be formed of polycrystalline silicon.

Referring to FIG. 10D, the vertical sacrificial structure in a region corresponding to the contact plug 170 in the second region R2 may be removed to form first contact holes, and preliminary contact insulating layers 125P and vertical sacrificial layers 191 may be formed in the first contact holes, and the sacrificial insulating layers 118 may be removed.

The vertical sacrificial structure disposed in a position of the separation regions MS (see FIG. 2A) may be removed to form openings, an etch-back process may be performed while forming separate sacrificial spacer layers within the openings, so that the horizontal sacrificial layer 110 in the first region R1 may be selectively removed, and a portion of an exposed first gate dielectric layer 145 may also be removed. After forming a first horizontal conductive layer 102 by depositing a conductive material in a region from which the horizontal sacrificial layer 110 is removed, the sacrificial spacer layers may be removed within the openings. By this process, a first horizontal conductive layer 102 may be formed in the first region R1.

Referring to FIG. 10E, gate electrodes 130 may be formed. The gate electrodes 130 may be formed by depositing a conductive material in regions from which the sacrificial insulating layers 118 are removed. The conductive material may include a metal, polycrystalline silicon, or a metal silicide material. In some example embodiments, a portion of the first gate dielectric layer 145 may be formed before forming the gate electrodes 130. When the gate electrodes are formed, the openings may be filled with an insulating material to form a separation region MS.

Referring to FIG. 10F, a first upper insulating layer 192 may be formed on the stack structure and the cell region insulating layer 190, and a second opening OP2 exposing an upper surface of the sacrificial guard ring structure may be formed on the first upper insulating layer 192. Second openings OP2 exposing some of the vertical sacrificial structures may be formed on the vertical sacrificial structures. As in FIG. 11B, the second openings OP2 may be formed to be spaced apart from one another by a separation distance on the upper surface of the sacrificial guard ring structure, and the first upper insulating layer 192 may remain in the spaced region.

Next, the sacrificial guard ring structure may be removed through the second opening OP2 to form a guard ring opening (see FIG. 10F).

Accordingly, when forming the guard ring opening, a portion of the first upper insulating layer 192 may remain in a lattice shape in an elongated opening that is long in the vertical direction corresponding to the first body portion 301a and also long in the extension direction, so that the opening of the first body portion 301a may be prevented from being tilted. Accordingly, when forming the outer guard ring structure GR2 concentrically in proximity to the inner guard ring structure GR1, even when two adjacent elongated openings are formed, the process may be advanced while securing structural stability by having a lattice-shaped support structure in an upper portion thereof.

The vertical sacrificial layers 191 may be selectively removed with respect to the interlayer insulating layers 120 and the gate electrodes 130. Some of the preliminary contact insulating layers 125P exposed after the vertical sacrificial layers 191 are removed may also be removed.

Referring to FIG. 10G, after forming a first diffusion barrier 400a on a side surface and a lower surface of the guard ring opening and the second opening OP2, a first metal layer 401 may be buried on the first diffusion barrier 400a to form a first structure 301.

Accordingly, as in FIG. 11C, the second openings OP2 may be buried to form first protrusion portions 301b, and the first protrusion portions 301b may be spaced apart from one another. The first body portion 301a may be formed by burying the guard ring opening through the second openings OP2.

A separation space between the first protrusion portions 301b may be the first recess portion G1 illustrated in FIG. 3B, and the first upper insulating layer 192 may remain therein.

Referring to FIG. 10H, a second upper insulating layer 194 may be formed on the first upper insulating layer 192. Third openings OP3 opening upper ends of the channel structures CH, the contact plugs 170 and the through-contact plugs 175 and a fourth opening OP4 exposing an upper surface of the first structure 301 may be formed in the second upper insulating layer 194. A fifth opening OP5 penetrating through both the first and second upper insulating layers 192 and 194 may be formed on an upper surface of the first structure 301 in which the second opening OP2 is not formed in the first upper insulating layer 192.

Specifically, referring to FIG. 11D, the fourth opening OP4 may be formed by forming a first opening region OP4-1 and a third opening region OP3 penetrating through the second upper insulating layer 194, and forming a second opening region OP4-2 removing the first upper insulating layer 192 remaining below the first opening region. A first upper insulating pattern 192P, which is a portion of the first upper insulating layer 192, may remain between a side surface of the second opening region OP4-2 and the first structure 301.

Referring to FIG. 11E, the first upper insulating pattern 192P may be removed through an etching process to form the fifth opening OP5.

Next, after forming a second diffusion barrier 400b on side surfaces and lower surfaces of the third and fifth openings OP3 and OP5, the second metal layer 402 may be buried on the second diffusion barrier 400b to form a second structure 302 as illustrated in FIGS. 2A and 2B.

When the fifth openings OP5 are buried, second protrusion portions 302b may be formed, and the second protrusion portions 302b may be spaced apart from one another.

The second recess portion G2, which is a separation space between the second protrusion portions 302b, may be filled with the first protrusion portions 301b.

As described above, at least a portion of a side surface of the first protrusion portions 301b and at least a portion of a side surface of the second protrusion portions 302b may be disposed to contact one another, and the first structure 301 and the second structure 302 may be wedge-bonded to one another to form a single wall structure.

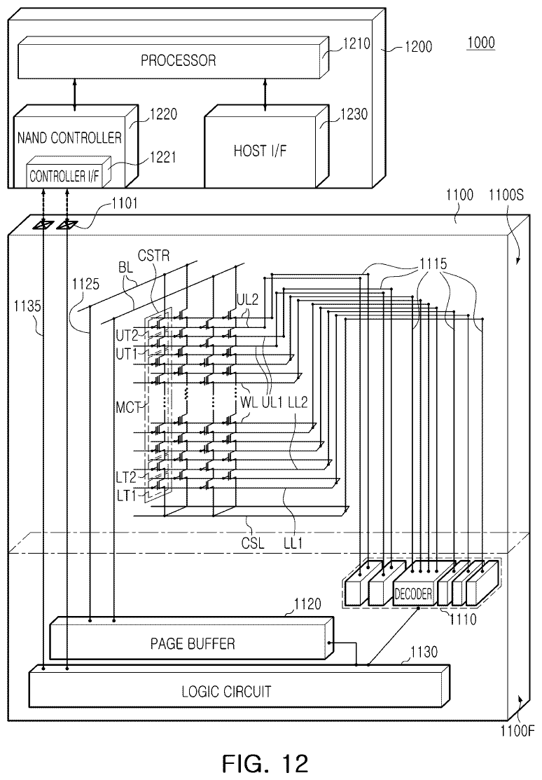

FIG. 12 is a schematic diagram of a data storage system including a semiconductor device according to example embodiments of the present disclosure.

Referring to FIG. 12, a data storage system 1000 may include a semiconductor device 1100 and a controller 1200 electrically connected to the semiconductor device 1100. The data storage system 1000 may be a storage device including one or more semiconductor devices 1100 or an electronic device including the storage device. For example, the data storage system 1000 may be a solid state drive device (SSD), a Universal Serial Bus (USB), a computing system, a medical device, or a communication device including one or more semiconductor devices 1100.

The semiconductor device 1100 may be a nonvolatile memory device, and may be, for example, a NAND flash memory device described above with reference to FIGS. 1 to 8. The semiconductor device 1100 may include a first structure 1100F and a second structure 1100S on the first structure 1100F. In example embodiments, the first structure 1100F may be disposed next to the second structure 1100S. The first structure 1100F may be a peripheral circuit structure including a decoder circuit 1110, a page buffer 1120, and a logic circuit 1130. The second structure 1100S may be a memory cell structure including a bit line BL, a common source line CSL, word lines WL, first and second gate upper lines UL1 and UL2, first and second gate lower lines LL1 and LL2, and memory cell strings CSTR between the bit line BL and the common source line CSL.

In the second structure 1100S, each memory cell string CSTR may include lower transistors LT1 and LT2 adjacent to the common source line CSL, upper transistors UT1 and UT2 adjacent to a bit line BL, and a plurality of memory cell transistors MCT disposed between the lower transistors LT1 and LT2 and the upper transistors UT1 and UT2. The number of lower transistors LT1 and LT2 and the number of upper transistors UT1 and UT2 may be variously changed depending on example embodiments.

In example embodiments, the upper transistors UT1 and UT2 may include string select transistors, and the lower transistors LT1 and LT2 may include ground select transistors. The gate lower lines LL1 and LL2 may be gate electrodes of the lower transistors LT1 and LT2, respectively. The word lines WL may be gate electrodes of the memory cell transistors MCT, and the gate upper lines UL1 and UL2 may be gate electrodes of the upper transistors UT1 and UT2, respectively.

In example embodiments, the lower transistors LT1 and LT2 may include a lower erase control transistor LT1 and a ground select transistor LT2 which are serially connected. The upper transistors UT1 and UT2 may include a string select transistor UT1 and an upper erase control transistor UT2 which are serially connected. At least one of the lower erase control transistor LT1 and the upper erase control transistor UT2 may be used for an erase operation of erasing data stored in the memory cell transistors MCT by utilizing the GIDL phenomenon.

The common source line CSL, the first and second gate lower lines LL1 and LL2, the word lines WL and the first and second gate upper lines UL1 and UL2 may be electrically connected to the decoder circuit 1110 through first interconnection lines 1115 extending from the first structure 1100F to the second structure 1100S. The bit lines BL may be electrically connected to the page buffer 1120 through second interconnection lines 1125 extending from the first structure 1100F to the second structure 1100S.

In the first structure 1100F, the decoder circuit 1110 and the page buffer 1120 may perform a control operation for at least one selected memory cell transistor among the plurality of memory cell transistors MCT. The decoder circuit 1110 and the page buffer 1120 may be controlled by the logic circuit 1130. The semiconductor device 1100 may communicate with the controller 1200 through an input/output pad 1101 that is electrically connected to the logic circuit 1130. The input/output pad 1101 may be electrically connected to the logic circuit 1130 through input/output interconnection lines 1135 that extending from the first structure 1100F to the second structure 1100S.

The controller 1200 may include a processor 1210, a NAND controller 1220, and a host interface 1230. According to example embodiments, the data storage system 1000 may include a plurality of semiconductor devices 1100, and in this case, the controller 1200 may control the plurality of semiconductor devices 1100.

The processor 1210 may control an overall operation of the data storage system 1000 including the controller 1200. The processor 1210 may operate according to a predetermined firmware, and may control the NAND controller 1220 to access the semiconductor device 1100. The NAND controller 1220 may include a controller interface 1221 processing communication with the semiconductor device 1100. Through the controller interface 1221, a control command for controlling the semiconductor device 1100, data to be written to the memory cell transistors MCT of the semiconductor device 1100, data to be read from the memory cell transistors MCT of the semiconductor device 1100, and the like, may be transmitted. The host interface 1230 may provide a communication function between the data storage system 1000 and the external host. When receiving a control command from the external host through the host interface 1230, the processor 1210 may control the semiconductor device 1100 in response to the control command.

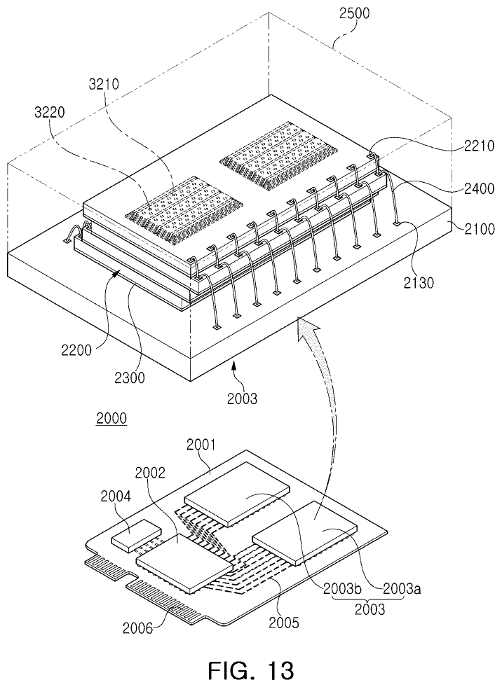

FIG. 13 is a perspective view schematically illustrating a data storage system including a semiconductor device according to example embodiments.

Referring to FIG. 13, a data storage system 2000 according to example embodiments of the present disclosure may include a main board 2001, a controller 2002 mounted on the main board 2001, one or more semiconductor packages 2003, and a DRAM 2004. The semiconductor package 2003 and the DRAM 2004 may be connected to one another with the controller 2002 by interconnection patterns 2005 formed on the main board 2001.

The main board 2001 may include a connector 2006 including a plurality of pins coupled to the external host. The number and arrangement of the plurality of pins in the connector 2006 may be changed depending on the communication interface between the data storage system 2000 and the external host. In example embodiments, the data storage system 2000 may communicate with the external host according to any one of the following interfaces: Universal Serial Bus (USB), Peripheral Component Interconnect Express (PCI-Express), Serial Advanced Technology Attachment (SATA), M-Phy for Universal Flash Storage (UFS). In example embodiments, the data storage system 2000 may operate by power supplied from the external host through the connector 2006. The data storage system 2000 may further include a Power Management Integrated Circuit (PMIC) distributing power supplied from the external host to the controller 2002 and the semiconductor package 2003.

The controller 2002 may write data to the semiconductor package 2003 or may read data from the semiconductor package 2003, and can improve the operation speed of the data storage system 2000.

The DRAM 2004 may be a buffer memory for alleviating a speed difference between the semiconductor package 2003, which is a data storage space, and the external host. The DRAM 2004 included in the data storage system 2000 may also operate as a type of cache memory, and may also provide a space for temporarily storing data in a control operation for the semiconductor package 2003. When the data storage system 2000 includes the DRAM 2004, the controller 2002 may further include a DRAM controller for controlling the DRAM 2004 in addition to the NAND controller for controlling the semiconductor package 2003.

The semiconductor package 2003 may include first and second semiconductor packages 2003a and 2003b spaced apart from one another. Each of the first and second semiconductor packages 2003a and 2003b may be a semiconductor package including a plurality of semiconductor chips 2200. Each of the first and second semiconductor packages 2003a and 2003b may include a package substrate 2100, semiconductor chips 2200 on the package substrate 2100, adhesive layers 2300 disposed on lower surfaces of each of the semiconductor chips 2200, a connection structure 2400 electrically connecting the semiconductor chips 2200 and the package substrate 2100, and a molding layer 2500 covering the semiconductor chips 2200 and the connection structure 2400 on the package substrate 2100.

The package substrate 2100 may be a printed circuit board including package upper pads 2130. Each semiconductor chip 2200 may include an input/output pad 2210. The input/output pad 2210 may correspond to the input/output pad 1101 of FIG. 8. Each of the semiconductor chips 2200 may include gate stack structures 3210 and channel structures 3220. Each of the semiconductor chips 2200 may include the semiconductor device described above with reference to FIGS. 1 to 9.

In example embodiments, the connection structure 2400 may be a bonding wire electrically connecting the input/output pad 2210 and the package upper pads 2130. Accordingly, in each of the first and second semiconductor packages 2003a and 2003b, the semiconductor chips 2200 may be electrically connected to one another in a bonding wire manner and may be electrically connected to the package upper pads 2130 of the package substrate 2100. According to example embodiments, in each of the first and second semiconductor packages 2003a and 2003b, the semiconductor chips 2200 may be electrically connected to one another by a connecting structure including a through-silicon via (TSV), instead of a connecting structure 2400 in a bonding wire manner.

In example embodiments, the controller 2002 and the semiconductor chips 2200 may be included in a single package. In example embodiments, a controller 2002 and semiconductor chips 2200 may be mounted on a separate interposer substrate different from the main substrate 2001, and the controller 2002 and semiconductor chips 2200 may be connected to one another by interconnection lines formed on the interposer substrate.

What is claimed is:

1. A semiconductor device, comprising:
a substrate including an active region and an edge region surrounding the active region;
a stack structure including a plurality of gate electrodes stacked and spaced apart from one another in a first direction, substantially perpendicular to an upper surface of the substrate, in the active region;
a channel structure penetrating through the stack structure in the first direction and including a channel layer;
a cell region insulating layer disposed in the edge region;
an upper insulating layer disposed on the cell region insulating layer; and
a guard ring structure surrounding the active region and penetrating through the cell region insulating layer and the upper insulating layer, in the edge region,
wherein the guard ring structure includes:
a first structure including a first body portion penetrating through the cell region insulating layer from the substrate and extending in a second direction, substantially perpendicular to the first direction, and first protrusion portions protruding from an upper surface of the first body portion and spaced apart from one another; and
a second structure including second body portion penetrating through the upper insulating layer so as to overlap the first structure in the first direction on the first structure, and second protrusion portions protruding from a lower surface of the second body portion and spaced apart from one another,
wherein the first protrusion portions and the second protrusion portions are disposed alternately in the second direction.

2. The semiconductor device of claim 1, wherein at least a portion of a side surface of the first protrusion portions is in contact with at least a portion of a side surface of the second protrusion portions.

3. The semiconductor device of claim 1, wherein:
the first structure further includes first recess portions disposed between the first protrusion portions,
the second structure further includes second recess portions disposed between the second protrusion portions, and
the second protrusion portions fill the first recess portions, and the first protrusion portions fill the second recess portions.

4. The semiconductor device of claim 1, wherein the first structure includes:
a first diffusion barrier disposed on a side surface and a lower surface of the first body portion and side surfaces of the first protrusion portions; and
a first metal layer disposed on the first diffusion barrier, and
the second structure includes:
a second diffusion barrier disposed on a side surface and a lower surface of the second body portion and side surfaces and lower surfaces of the first protrusion portions; and
a second metal layer disposed on the second diffusion barrier.

5. The semiconductor device of claim 1, wherein on a central level of the first protrusion portions and the second protrusion portions in the first direction, a length of the first protrusion portions in the second direction and a length of the second protrusion portions in the second direction are approximately equal to one another.

6. The semiconductor device of claim 1, wherein at least portions of upper surfaces of the first protrusion portions are in contact with the lower surface of the second body portion, and lower surfaces of the second protrusion portions are in contact with at least a portion of the upper surface of the first body portion.

7. The semiconductor device of claim 1, wherein the first body portion has a width of the upper surface greater than a width of a lower surface and includes an inclined side surface between the upper surface and the lower surface, and the second body portion has a width of an upper surface greater than a width of the lower surface and includes an inclined side surface between the upper surface and the lower surface, and
the width of the upper surface of the second body portion is greater than a width of an upper surface of the first protrusion portion.

8. The semiconductor device of claim 7, wherein the width of the upper surface of the second body portion is less than the width of the upper surface of the first body portion.

9. The semiconductor device of claim 1, wherein a length of the first body portion in the first direction is greater than a length of the second body portion in the first direction, and a length of the first protrusion portion in the first direction is approximately equal to a length of the second protrusion portion in the first direction.

10. The semiconductor device of claim 1, wherein the first protrusion portions have a cross-sectional area that decreases from an upper surface to a lower surface, and
the second protrusion portions have a cross-sectional area that increases from an upper surface to a lower surface.

11. A semiconductor device, comprising:
a substrate including an active region and an edge region surrounding the active region;
a stack structure including a plurality of gate electrodes stacked and spaced apart from one another in a first direction, substantially perpendicular to an upper surface of the substrate in the active region;
a channel structure penetrating through the stack structure in the first direction and including a channel layer;
a cell region insulating layer disposed in the edge region;
an upper insulating layer disposed on the cell region insulating layer;
an inner guard ring structure surrounding the active region, penetrating through the cell region insulating layer and the upper insulating layer, and extending in a second direction, substantially perpendicular to the first direction, in the edge region; and
an outer guard ring structure surrounding the inner guard ring structure and spaced apart from the inner guard ring structure in a third direction, substantially perpendicular to the first direction and the second direction,
wherein each of the inner guard ring structure and the outer guard ring structure includes:
a first structure including a first body portion penetrating through the cell region insulating layer from the substrate and extending in the second direction, first protrusion portions protruding from an upper surface of the first body portion and spaced apart from one another, and first recess portions between the first protrusion portions; and
a second structure penetrating through the upper insulating layer so as to overlap the first structure in the first direction on the first structure,
wherein the first recess portions of the inner guard ring structure are offset from the first recess portions of the outer guard ring structure in the third direction.

12. The semiconductor device of claim 11, wherein:
each of the inner guard ring structure and the outer guard ring structure is configured to
on a central level of the first protrusion portions in the first direction, each of the first protrusion portions has a first length in the second direction,
each of the first recess portions has a second length in the second direction, and
the first length and the second length are approximately equal to one another.

13. The semiconductor device of claim 11, wherein:
each of the inner guard ring structure and the outer guard ring structure is configured to
on a central level of the first protrusion portions in the first direction, each of the first protrusion portions has a first length in the second direction,
each of the first recess portions has a second length in the second direction, and
the first length is greater than the second length.

14. The semiconductor device of claim 11, wherein in each of the inner guard ring structure and the outer guard ring structure,
the second structure includes:
a second body portion penetrating through the upper insulating layer so as to overlap the first structure in the first direction on the first structure;
second protrusion portions protruding from a lower surface of the second body portion and spaced apart from one another; and
second recess portions between the second protrusion portions.

15. The semiconductor device of claim 14, wherein in each of the inner guard ring structure and the outer guard ring structure,
a first width of the first protrusion portions in the third direction is greater than a second width of the second protrusion portions in the third direction.

16. The semiconductor device of claim 14, wherein in each of the inner guard ring structure and the outer guard ring structure,
a first width of the first protrusion portions in the third direction is less than a second width of the second protrusion portions in the third direction.

17. The semiconductor device of claim 14, wherein in each of the inner guard ring structure and the outer guard ring structure,
at least portions of side surfaces of the first protrusion portions and at least portions of side surfaces of the second protrusion portions contact one another.

18. The semiconductor device of claim 11, wherein the first protrusion portions of the inner guard ring structure overlap the first protrusion portions of the outer guard ring structure in the third direction.

19. The semiconductor device of claim 11, wherein a width of the upper surface of the first body portion of the inner guard ring structure in the third direction is greater than a width of an upper surface of the first body portion of the outer guard ring structure in the third direction.

20. A data storage system, comprising:
a semiconductor device including an input/output pad; and
a controller electrically connected to the semiconductor device through the input/output pad and configured to control the semiconductor device,
wherein the semiconductor device includes:
a substrate including an active region and an edge region surrounding the active region;
a stack structure including a plurality of gate electrodes stacked and spaced apart from one another in a first direction, substantially perpendicular to an upper surface of the substrate in the active region;
a channel structure penetrating through the stack structure in the first direction and including a channel layer;
a cell region insulating layer disposed in the edge region;
an upper insulating layer disposed on the cell region insulating layer;
an inner guard ring structure surrounding the active region, penetrating through the cell region insulating layer and the upper insulating layer, and extending in a second direction, substantially perpendicular to the first direction, in the edge region; and
an outer guard ring structure surrounding the inner guard ring structure and spaced apart from the inner guard ring structure in a third direction, substantially perpendicular to the first and second directions,
wherein each of the inner guard ring structure and the outer guard ring structure includes:
a first structure including a first body portion penetrating through the cell region insulating layer from the substrate and extending in the second direction, first protrusion portions protruding from an upper surface of the first body portion and spaced apart from one another, and first recess portions between the first protrusion portions; and
a second structure penetrating through the upper insulating layer so as to overlap the first structure in the first direction on the first structure, and
the first recess portions of the inner guard ring structure have a structure that is offset from the first recess portions of the outer guard ring structure in the third direction.
